(19) United States
(12) Patent Application Publication
(10) Pub. No.: US 2023/0282643 A1
(43) Pub. Date: Sep. 7, 2023

(54) THREE-DIMENSIONAL DEVICE AND METHOD OF FORMING THE SAME

(71) Applicant: Tokyo Electron Limited, Tokyo (JP)

(72) Inventors: Mark I. GARDNER, Cedar Creek, TX (US); H. Jim FULFORD, Marianna, FL (US)

(73) Assignee: Tokyo Electron Limited, Tokyo (JP)

(21) Appl. No.: 17/685,025

(22) Filed: Mar. 2, 2022

(51) Int. Cl. H01L 27/092; H01L 29/06; H01L 29/423; H01L 29/417; H01L 29/786; H01L 21/02; H01L 21/8238; H01L 29/66

(52) U.S. Cl. CPC H01L 27/0922; H01L 29/0665; H01L 29/42392; H01L 29/41733; H01L 29/78642; H01L 29/78618; H01L 29/78696; H01L 21/0259; H01L 21/823807; H01L 21/823814; H01L 21/823871; H01L 21/823885; H01L 29/66742

(57) ABSTRACT

According to an aspect of the disclosure, a semiconductor device is provided. The semiconductor device includes a stack of channel layers positioned over a substrate, where the channel layers are spaced apart from one another. The semiconductor device includes source/drain (S/D) structures positioned at a first side and a second side of the stack of channel layers and in contact with the channel layers, where the first side is opposite to the second side. The semiconductor device includes gate dielectric layers arranged around the channel layers, and gate electrodes surrounding the gate dielectric layers and further extending from a third side and a fourth side of the stack of channel layers, where the third side is opposite to the fourth side. The semiconductor device further includes a seed layer positioned over the stack of channel layers.

### FIELD OF THE INVENTION

The disclosure relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques herein include methods and devices for 3D fabrication of semiconductor devices. Specifically, techniques include making a completed lower 3D transistor nano sheet with an epi seed layer on top such that another subsequent 3D transistor stack may be utilized. Techniques herein enable vertical nano sheets to be stacked on horizontal nano sheets to increase 3D circuit layout. In the disclosure, any type of nano sheet can be used to the lower 3D completed transistor paired with one or more devices on the top nano sheet. The top nano sheet can be any type of nano sheet also. 3D nano sheet stacks include horizontal, vertical, cylinder, nanowires, ellipse or any shape. In the disclosure, a partial epi seed layer can be applied such that a portion of the epi seed layer is utilized to grow a new 3D nano sheet stack on the top of the completed 3D devices. In the disclosure, wiring and building of nano sheets can be implemented along with the formation of the stack 3D circuit. Accordingly, layout efficiency is greatly enhanced. In the disclosure, all kinds of device types may be utilized on the epi seed layer since the epi seed layer is analogous to a new semiconductor substrate to build a fresh set of devices and circuits. The introduction of an epitaxial seed layer provides more 3D stacking with options of different nano sheet types for optimum 3D circuit design.

In a first manufacturing flow of the disclosure, an epi seed layer can be introduced to function as a substrate to form an upper 3D vertical transistor nano sheet on top of a 3D stack of nano sheets. The first manufacturing flow can apply a nano sheet without a source/drain (S/D) structure and a disposable gate all around (GAA) structure to form the epi seed layer. In an example, an epi seed layer can be introduced by using a dummy nano sheet. The first manufacturing flow can be placed on any existing stack of horizontal Nano sheets.

In a second manufacturing flow, a lower completed 3D nano sheet stack can be formed to include N (e.g., N=4) layers over a substrate. The 3D nano sheet stack can contain a horizontal device nano sheet with an epi seed layer. The horizontal device can be a NMOS or a PMOS. The epi seed layer can function as a substrate to form an upper 3D vertical device stack nano sheet (may be circular, rectangular, or any shape). In some embodiment, a metal last process can be applied for the lower stack, and a metal first process can be applied for the upper stack in S/D regions and a metal last process can be applied for the upper stack in gate electrodes. In some embodiment, in the lower stack, a NMOS and a PMOS can be positioned side by side over the substrate. In some embodiment, a first SiGe layer can be formed between the 3D nano sheet stack and the substrate and a second SiGe layer can be formed beneath the epi seed Layer. The first SiGe and the second SiGe layers can be replaced with a dielectric material to form isolation structures. Thus, a disposable GAA structure is not applied for forming the epi seed layer.

In a third manicuring flow of the disclosure, a complementary field-effect transistor (CFET) structure can be applied. The CFET structure can include N (e.g., N=4) layers as a bottom stack containing a horizontal device nano sheet with an epi seed layer to form an upper 3D vertical device stack nano sheet (may be circular, rectangular, or any shape). In some embodiments, a metal last process can be applied in the bottom stack and a metal first process can be applied for the upper 3D stack. Similar to the second manufacturing flow, a first SiGe layer can be formed between the 3D nano sheet stack and the substrate and a second SiGe layer can be formed beneath the epi seed Layer. The first SiGe and the second SiGe layers can be replaced with a dielectric material to form isolation structures. Thus, a disposable GAA structure is not applied for forming the epi seed layer.

Of course, an order of the manufacturing steps disclosed herein is presented for clarity sake. In general, these manufacturing steps can be performed in any suitable order. Additionally, although each of the different features, techniques, configurations, etc. herein may be discussed in different places of the present disclosure, it should be noted that each of the concepts can be executed independently from each other or in combination with each other. Accordingly, the present disclosure can be embodied and viewed in many different ways.

It should be noted that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

According to an aspect of the disclosure, a semiconductor device is provided. The semiconductor device can include a stack of channel layers positioned over a substrate, where the channel layers can be spaced apart from one another. The semiconductor device can include source/drain (S/D) structures positioned at a first side and a second side of the stack of channel layers and in contact with the channel layers, where the first side is opposite to the second side. The semiconductor device can include gate dielectric layers arranged around the channel layers, and gate electrodes surrounding the gate dielectric layers and further extending from a third side and a fourth side of the stack of channel layers, where the third side is opposite to the fourth side. The semiconductor device can further include a seed layer positioned over the stack of channel layers.

In some embodiments, a cross-section of the stack of channel layers obtained along a direction parallel to the substrate can have a quadrilateral shape that includes the first, second, third, and fourth sides.

The semiconductor device can include insulating layers positioned between the channel layers and arranged on the surfaces of the channel layers. The gate dielectric layers and the gate electrodes can be positioned between the insulating layers, and spaced apart from the S/D structures by the insulating layers.

In some embodiments, a high-k layer can further be disposed around the seed layer.

In the semiconductor device, a first high-k layer can be positioned between a first gate electrode of the gate electrodes and the substrate. A second high-k layer can be positioned between a second gate electrode of the gate electrodes and the substrate. A first dielectric layer can be positioned between a first S/D structure of the S/D structures and the substrate. A second dielectric layer can be positioned between a second S/D structure of the S/D structures and the substrate.

In the semiconductor device, the channel layers can further include n-type channel layers and p-type channel layers that are stacked over the substrate. The gate electrodes can further include n-type gate electrodes and p-type gate electrodes that are stacked over the substrate, where the n-types gate electrodes can be arranged around the n-type channel layers, and the p-types gate electrodes can be arranged around the p-type channel layers. The S/D structures can further include n-type S/D structures and p-type S/D structures that are stacked over the substrate. The n-type channel layers can be positioned between and coupled to the n-type S/D structures, and the p-type channel layers can be positioned between and coupled to the p-type S/D structures.

In some embodiments, the n-type S/D structures and n-type channel layers can be made of silicon that is epitaxially deposited and doped with a n-type dopant. The p-type S/D structures and p-type channel layers can be made of silicon that is epitaxially deposited and doped with a p-type dopant.

The semiconductor device can further include an isolation layer positioned between a lowermost gate structure of the gate structures and the substrate.

The semiconductor device can include a stack of insulating layers and interconnect layers that are positioned alternatingly over the stack of channel layers. The semiconductor device can include a channel structure positioned over the seed layer and extending through the insulating layers and the interconnect layers. The channel structure can include a first channel section positioned over the seed layer and coupled to a first group of the interconnect layers, and a second channel section positioned over the first channel section and coupled to a second group of the interconnect layers.

In some embodiments, a first S/D region of the first channel section can be formed over the seed layer and in contact with a first interconnect layer of the first group of the interconnect layers. A first gate region of the first channel section can be formed over the first S/D region of the first channel section. The first gate region can include (i) a first channel region over the first S/D region and (ii) a first gate oxide around the first channel region and in contact with a second interconnect layer of the first group of the interconnect layers. A second S/D region of the first channel section can be formed over the first gate region and in contact with a third interconnect layer of the first group of the interconnect layers. A third S/D region of the second channel section can be formed over the second S/D region and in contact with a first interconnect layer of the second group of the interconnect layers. A second gate region of the second channel section can be formed over the third S/D region. The second gate region can include (i) a second channel region over the third S/D region and (ii) a second gate oxide around the second channel region and in contact with a second interconnect layer of the second group of interconnect layers. A fourth S/D region of the second channel section can be formed over the second gate region and in contact with a third interconnect of the second group of interconnect layers.

The semiconductor device can further include a first dielectric layer positioned between the seed layer and the first S/D region of the first channel section, a second dielectric layer positioned between the second S/D region of the first channel section and the third S/D region of the second channel section, a third dielectric layer positioned over the fourth S/D region of the second channel section, and an isolation structure extending from the first dielectric layer and further through the first channel section, the second dielectric layer, the second channel section, and the third dielectric layer.

According to another aspect of the disclosure, a semiconductor device is provided. The semiconductor device can include a horizontal transistor over a substrate. The horizontal transistor can include (i) a stack of channel layers over the substrate and extending parallel to a main surface of the substrate, (ii) S/D structures positioned at a first side and an opposing second side of the stack of channel layers, and (iii) gate structures surrounding the channel layers and further extending from a second side and an opposing third side of the stack of channel layers. The semiconductor device can include a seed layer positioned over the stack of channel layers, and a vertical transistor positioned over the horizontal transistor. The vertical transistor can include a stack of insulating layers and interconnect layers over the stack of channel layers, and a channel structure positioned over the seed layer and extending through the insulating layers and the interconnect layers in a direction orthogonal to the main surface of the substrate. The channel structure can include a first channel section positioned over the seed layer and coupled to a first group of the interconnect layers, and a second channel section positioned over the first channel section and coupled to a second group of the interconnect layers.

The horizontal transistor can further include n-type channel layers and p-type channel layers that are stacked over the substrate. The gate structures can further include n-type gate structures and p-type gate structures. The n-types gate structures can be positioned around the n-type channel layers, and the p-types gate structures can be positioned around the p-type channel layers. The S/D structures can further include n-type S/D structures and p-type S/D structures that are stacked over the substrate. The n-type channel layers can be positioned between and coupled to the n-type S/D structures, and the p-type channel layers can be positioned between and coupled to the p-type S/D structures.

In the vertical transistor, a first S/D region of the first channel section can be formed over the seed layer and in contact with a first interconnect layer of the first group of the interconnect layers. A first gate region of the first channel section can be formed over the first S/D region of the first channel section. The first gate region can include (i) a first channel region over the first S/D region and (ii) a first gate oxide around the first channel region and in contact with a second interconnect layer of the first group of the interconnect layers. A second S/D region of the first channel section can be formed over the first gate region and in contact with a third interconnect layer of the first group of the interconnect layers. A third S/D region of the second channel section can be formed over the second S/D region and in contact with a first interconnect layer of the second group of the interconnect layers. A second gate region of the second channel section can be formed over the third S/D region. The second gate region can include (i) a second channel region over the third S/D region and (ii) a second gate oxide around the second channel region and in contact with a second interconnect layer of the second group of the interconnect layers. A fourth S/D region of the second channel section can be formed over the second gate region and in contact with a third interconnect of the second group of the interconnect layers.

According to yet another aspect of the disclosure, a method of forming a semiconductor device is provided. In the method, a stack of alternating channel layers and intermediate layers can be formed over a substrate. Source/drain (S/D) structures can be formed at a first side and a second side of the stack and in contact with the channel layers, where the first side can be opposite to the second side. The intermediate layers can be replaced with gate structures. The gate structures can include (i) gate dielectric layers arranged around the channel layers, and (ii) gate electrodes surrounding the gate dielectric layers and further extending from a third side and a fourth side of the stack of channel layers, where the third side is opposite to the fourth side. A seed layer can be formed over the stack of alternating channel layers and intermediate layers.

In the method, before the S/D structures are formed, the intermediate layers can be recessed from the first side and the second side of the stack. Insulating layers can be formed between the channel layers such that the intermediate layers are positioned between the insulating layers.

In the method, a first high-k layer can be formed between a first gate electrode of the gate electrodes and the substrate. A second high-k layer can be formed between a second gate electrode of the gate electrodes and the substrate. A first dielectric layer can be formed between a first S/D structure of the S/D structures and the substrate. A second dielectric layer can be formed between a second S/D structure of the S/D structures and the substrate.

In the method, a high-k layer can be formed around the seed layer.

In some embodiments, the channel layers can further include n-type channel layers and p-type channel layers that are stacked over the substrate. The gate structures can further include n-type gate structures and p-type gate structures, where the n-types gate structures can be positioned between the n-type channel layers and arranged on the surfaces of the n-type channel layers, and the p-types gate structures can be positioned between the p-type channel layers and arranged on the surfaces of the p-type channel layers. The S/D structures can further include n-type S/D structures and p-type S/D structures. The n-type channel layers can be positioned between and coupled to the n-type S/D structures, and the p-type channel layers can be positioned between and coupled to the p-type S/D structures.

In the method, a stack of insulating layers and interconnect layers can be formed to be positioned alternatingly over the stack of alternating channel layers and intermediate layers. A channel structure can be formed that is positioned over the seed layer and extend through the insulating layers and the interconnect layers. The channel structure can include a first channel section positioned over the seed layer and coupled to a first group of the interconnect layers, and a second channel section positioned over the first channel section and coupled to a second group of the interconnect layers.

In order to form the channel structure, a first opening can be formed to extend through the insulating layers and the interconnect layers such that the seed layer is uncovered. A first sacrificial layer can be formed on the seed layer. A first S/D region of the first channel section can be formed over the first sacrificial layer, a first gate region of the first channel section can be formed over the first S/D region, and a second S/D region of the first channel section can be formed over the first gate region. A second sacrificial layer can be formed over the second S/D region of the first channel section. A third S/D region of the second channel section can be formed over the second sacrificial layer, a second gate region of the second channel section can be formed over the third S/D region, and a fourth S/D region of the second channel section can be formed over the second gate region. A second opening can be formed to extend through the fourth S/D region, the second gate region, the third S/D region, the second sacrificial layer, the second S/D region, the first gate region, the first S/D region, and the first sacrificial layer to uncover the seed layer. The first and second sacrificial layers can be removed to form a first space between the seed layer and the first S/D region and a second space between the second S/D region and the third S/D region. The second opening, the first space, and the second space can be filled with a dielectric material.

In some embodiments, the first S/D region can be in contact with a first interconnect layer of the first group of the interconnect layers. The first gate region can include (i) a first channel region over the first S/D region and (ii) a first gate oxide around the first channel region and in contact with a second interconnect layer of the first group of the interconnect layers. The second S/D region can be in contact with a third interconnect layer of the first group of the interconnect layers. The third S/D region can be in contact with a first interconnect layer of the second group of the interconnect layers. The second gate region can include (i) a second channel region over the third S/D region and (ii) a second gate oxide around the second channel region and in contact with a second interconnect layer of the second group of interconnect layers. The fourth S/D region can be in contact with a third interconnect of the second group of interconnect layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top down view of a first semiconductor device, in accordance with some embodiments.

FIG. 1B is a first cross-sectional view of the first semiconductor device, in accordance with some embodiments.

FIG. 1C is a second cross-sectional view of the first semiconductor device, in accordance with some embodiments.

FIG. 2 is a cross-sectional view of a second semiconductor device, in accordance with some embodiments.

FIGS. 3-43 are top-down views and cross-sectional views of various intermediate steps in a manufacturing flow to fabricate the first and second semiconductor devices, in accordance with some embodiments.

FIG. 44 is a cross-sectional view of a third semiconductor device, in accordance with some embodiments.

FIGS. 45-86 are top-down views and cross-sectional views of various intermediate steps in a manufacturing flow to fabricate the third semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the apparatus in use or operation in addition to the orientation depicted in the figures. The apparatus may be otherwise oriented (rotated 90 degrees or at other orientations) and the spatially relative descriptors used herein may likewise be interpreted accordingly.

Reference throughout the specification to “one embodiment” or “an embodiment” means that a particular feature, structure, material, or characteristic described in connection with the embodiment is included in at least one embodiment, but do not denote that they are present in every embodiment. Thus, the appearances of the phrases “in one embodiment” in various places through the specification are not necessarily referring to the same embodiment. Furthermore, the particular features, structures, materials, or characteristics may be combined in any suitable manner in one or more embodiments.

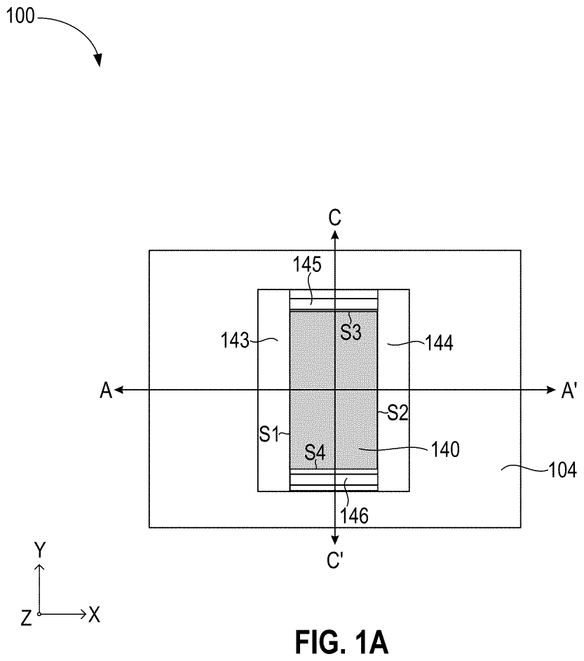

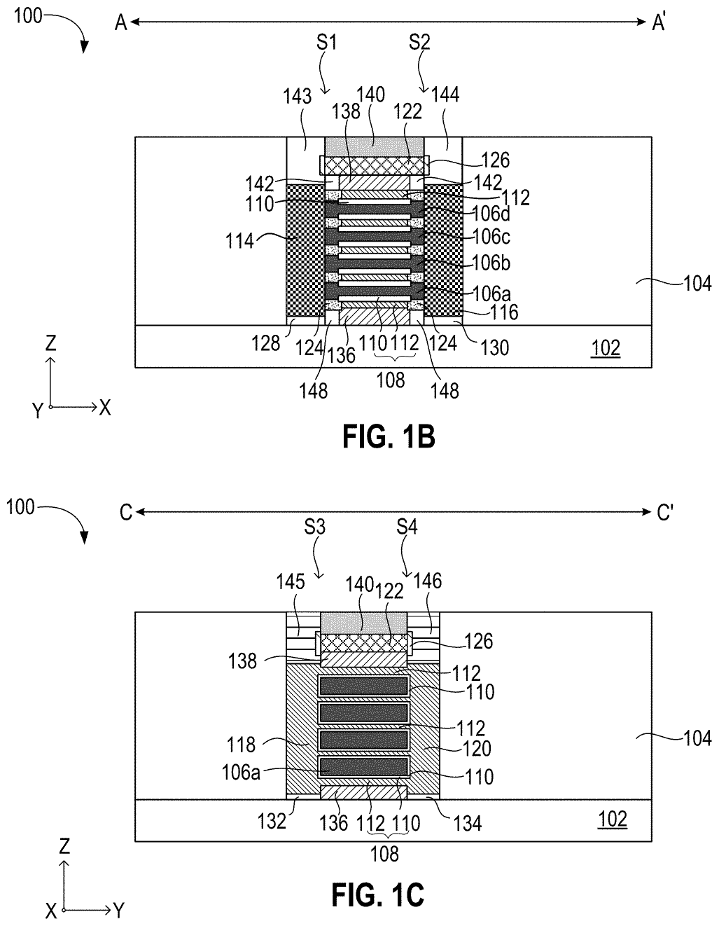

FIG. 1A is a top down view of a semiconductor device (or device 100). As shown in FIG. 1A, the device 100 can include a cap layer 140 under which a stack of channel layers (as shown in FIGS. 1B and 1C) can be formed over a substrate (as shown in FIGS. 1B and 1C). A structure 143 can be positioned at a first side 51 of the stack and a structure 144 positioned at a second side S2 of the stack. The first side 51 can be opposite to the second side S2. Further, a structure 145 can be positioned at a third side S3 of the stack and a structure 146 can be formed at a fourth side S4 of the stack. The third side S3 can be opposite to the fourth side S4. The structures 143-146 can further be formed in a dielectric layer 104.

In some embodiments, the structures 143-146 can be made of a dielectric material, such as SiO, SiN, SiON, SiC, SiOC, SiCN, SiOCN, the like, or a combination thereof. In some embodiments, the structures 143-146 can be made of a conductive material, such as W, Co, Ru, Cu, Al, or the like, and function as interconnect structures.

FIG. 1B is a cross-sectional view of the device 100, which can be obtained from a same plane as a vertical plane along line A-A′ in FIG. 1A. As shown in FIG. 1B, the device 100 can include a stack of channel layers 106a-106d positioned over a substrate 102, where the channel layers 106a-106d can be spaced apart from one another. The device 100 can include gate structures 108 positioned between the channel layers 106a-106d and arranged on surfaces of the channel layers 106a-106d. The channel layers 106a-106d can include Si, SiGe, Ge, or other semiconductor materials. It should be noted that FIG. 1B is merely an example, and the device 100 can include any number of channel layers.

Each of the gate structures 108 can further include a gate dielectric layer 110 positioned on the surfaces of the channel layers 106a-106d, and a gate electrode layer 112 positioned along and in contact with the gate dielectric layer 110. In some embodiments, the gate dielectric layer 110 can include SiO₂, HfO₂, ZrO₂, HfSiNO₂, ZrSiNO₂, Y₃O₄, Si₃N₄, Al₂O₃, the like, or a combination thereof. In some embodiments, the device 100 can be a n-type transistor. Accordingly, the gate electrode layer 112 can include a work function layer (e.g., TiC, AlTiC, AlTiO), a liner (e.g., TiN), and a filler (e.g., W or Ru). In some embodiments, the device 100 can be a p-type transistor. Accordingly, the gate electrode layer 112 can include a work function layer (e.g., TiON, TiC, AlTiN, AlTiC, AlTiO), a liner (e.g., TiN and/or TaN), and a filler (e.g., W or Ru).

The device 100 can include a first source/drain (S/D) structure 114 positioned at the first side S1 of the stack of channel layers 106a-106b, and a second S/D structure 116 positioned at the second side S2 of the stack of channel layers 106a-106d. The first and second S/D regions 114 and 116 can be in contact with the channel layers 106a-106d such that the channel layers 106a-106b are arranged between the first S/D structure 114 and the second S/D structure 116. The first S/D structure 114 and the second S/D structure 116 can include Si, SiGe, Ge, or other suitable semiconductor materials. The first S/D structure 114 and the second S/D structure 116 can be epitaxially grown by any suitable deposition process, such as a chemical vapor deposition (CVD), a diffusion process, and an atomic layer deposition (ALD). In some embodiments, the device 100 can be a n-type transistor. Thus, the first S/D structure 114 and the second S/D structure 116 can be n-type doped. In some embodiments, the device 100 can be a p-type transistor. Accordingly, the first S/D structure 114 and the second S/D structure 116 can be p-type doped.

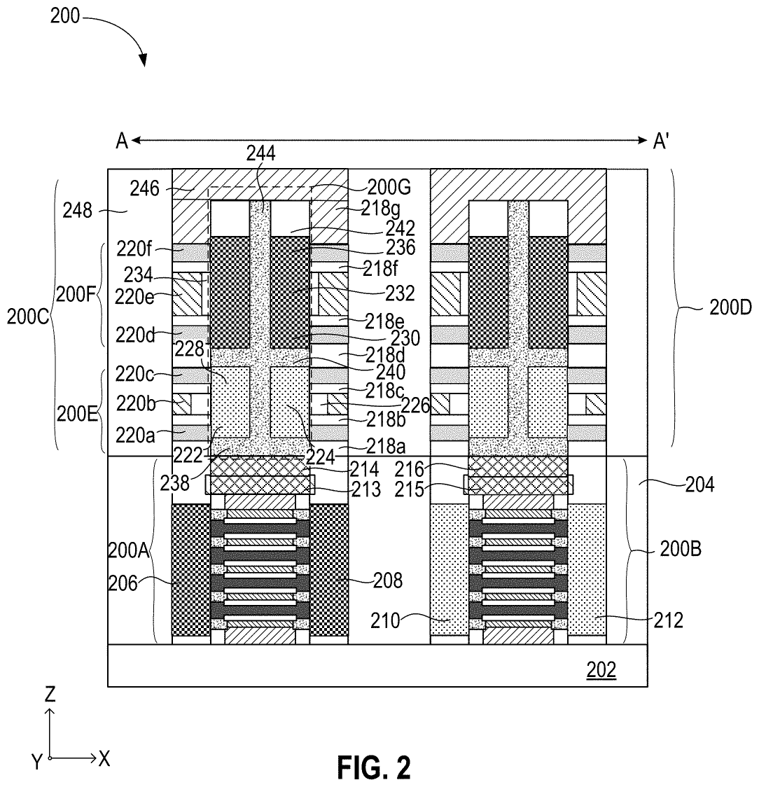

The device 100 can further include a seed layer 122 positioned over the stack of channel layers 106a-106d. The seed layer 122 can be an epitaxial growth layer that includes one of Si, SiGe, Ge, or other suitable semiconductor materials. The seed layer 122 can be configured to function as a substrate on which another subsequent 3D transistor stack can be formed. An exemplary of the formation of the other subsequent 3D transistor stack based on the seed layer 122 can be shown in FIG. 2.

In some embodiments, as shown in FIG. 1A, a cross-section of the stack of channel layers 106a-106d obtained along a direction (e.g., X-Y direction) parallel to the substrate 102 can have a quadrilateral shape that includes the first side S1, the second side S2, the third side S3, and the fourth side S4.

The device 100 can include insulating layers 124 positioned between the channel layers 106a-106d and arranged on the surfaces of the channel layers 106a-106d. The gate structures 108 can be positioned between the insulating layers 124, and spaced apart from the first and second S/D structures 114 and 116 by the insulating layers 124.

In some embodiments, a high-k layer 126 can further be disposed around the seed layer 122. The high-k layer 126 can be one of HfO₂, ZrO₂, HfSiNO₂, ZrSiNO₂, Y₃O₄, Si₃N₄, and Al₂O₃.

The device 100 can include a first isolation layer 136 positioned between a lowermost gate structure of the gate structures 108 and the substrate 102, where the lowermost gate structure is disposed on a bottom surface of the lowermost channel layer 106a. The device 100 can also include a second isolation layer 138 that is positioned between an uppermost gate structure of the gate structures 108 and the seed layer 122, where the uppermost gate structure is disposed over the uppermost channel layer 106d.

The device 100 can include a first dielectric layer 128 positioned between the first S/D structure 114 and the substrate 102, and a second dielectric layer 130 positioned between the second S/D structure 116 and the substrate 102. The device 100 can also include top dielectric layers 142 between which the second isolation layer 138 is positioned, and bottom dielectric layers 148 between which the first isolation layer 136 is positioned. In some embodiments, the first dielectric layer 128, the second dielectric layer 130, the top dielectric layers 142, and the bottom dielectric layers 148 can include SiO, SiN, SiON, SiC, SiOC, SiCN, SiOCN, or the like.

Still referring to FIG. 1B, the structure 143 can be positioned at the first side 51 of the stack of channel layers 106a-106d and further arranged over the first S/D structure 114, and the structure 144 can be positioned at the second side S2 of the stack of channel layers 106a-106d and further arranged over the second S/D structure 116.

FIG. 1C is a cross-sectional view of the device 100, which can be obtained from a same plane as a vertical plane along line C-C′ in FIG. 1A. As shown in FIG. 1C, the device can include a first gate electrode 118 positioned at the third side S3 of the stack of channel layers 106a-106d, a second gate electrode 120 positioned at the fourth side S4 of the stack of channel layers 106a-106d. The first and second gate electrodes can be in contact with the gate electrode layers 112. The gate structures 108 can include the first gate electrode 118, the second gate electrode 120, the gate electrode layers 112, and the gate dielectric layers 110. In some embodiments, the first gate electrode 118 and the second gate electrode 120 can include W, Co, or Ru. In some embodiments, the first gate electrode 118 and the second gate electrode 120 can also include work function layers (e.g., TiC, TiON, AlTiN, AlTiC, AlTiO, or the like) and the liners (e.g., TiN, TaN, or the like).

Still referring to FIG. 1C, the device 100 can include a first high-k layer 132 positioned between the first gate electrode 118 and the substrate 102, and a second high-k layer 134 positioned between the second gate electrode 120 and the substrate 102. The structure 145 can be positioned at the third side S3 of the stack of channel layers 106a-106d and further arranged over the first gate electrode 118, and the structure 146 can be positioned at the fourth side S4 of the stack of channel layers 106a-106d and further arranged over the second gate electrode 120.

FIG. 2 is a cross-sectional view of a semiconductor device (or device) 200, in accordance with some embodiments. As shown in FIG. 2, the device 200 can include a n-type transistor 200A and a p-type transistor 200B. The n-type transistor 200A and the p-type transistor 200B can be positioned over a substrate 202, arranged side by side, and spaced apart from one another by a dielectric layer 204. The n-type transistor 200A and a p-type transistor 200B can have similar configurations to the device 100 shown in FIGS. 1A, 1B, and 1C. In some embodiments, the cap layer 140 shown in device 100 can be replaced by a top seed layer. For example, a top seed layer 214 is positioned on the seed layer 213 in the n-type transistor 200A, and a top seed layer 216 is positioned on the seed layer 215 in the p-type transistor 200B. The n-type transistor 200A can include a first S/D structure 206 and a second S/D structure 208 that are n-type doped. The p-type transistor 200B can include a first S/D structure 210 and a second S/D structure 212 that are p-type doped.

The device 200 can include a first transistor stack 200C over the n-type transistor 200A and a second transistor stack 200D over the p-type transistor 200B. The first transistor stack 200C and the second transistor stack 200D can be arranged in a dielectric layer 248 and spaced apart from one another by the dielectric layer 248. For simplicity and clarity, features of the first transistor stack 200C and the second transistor stack 200D can be described based on the first transistor stack 200C. The second transistor stack 200D can have features similar to the first transistor stack 200C. As shown in FIG. 2, the first transistor stack 200C can include a stack of insulating layers 218a-218g and interconnect layers 220a-220f that are positioned alternatingly over the n-type transistor 200A. The first transistor stack 200C can include a channel structure 200G positioned over the top seed layer 214 and extending through the insulating layers 218a-218g and the interconnect layers 220a-220f. The channel structure 200G can include a first channel section 200E positioned over the top seed layer 214 and coupled to a first group of the interconnect layers 220a-220c, and a second channel section 200F positioned over the first channel section 200E and coupled to a second group of the interconnect layers 220d-220f.

In some embodiments, the first channel section 200E can include a first S/D region 222 that is positioned over the top seed layer 214 and in contact with a first interconnect layer 220a of the first group of the interconnect layers 220a-220c. The first channel section 200E can also include a first gate region over the first S/D region 222 of the first channel section 200E. The first gate region can include (i) a first channel region 224 over the first S/D region 222 and (ii) a first gate oxide 226 around the first channel region 224 and in contact with a second interconnect layer 220b of the first group of the interconnect layers 220a-220c. The first channel section 200E can include a second S/D region 228 over the first gate region and in contact with a third interconnect layer 220c of the first group of the interconnect layers 220a-220c.

The second channel section 200F can include a third S/D region 230 over the second S/D region 228 and in contact with a first interconnect layer 220d of the second group of the interconnect layers 220d-220f. The second channel section 200F can include a second gate region over the third S/D region 230. The second gate region can include (i) a second channel region 232 over the third S/D region 230 and (ii) a second gate oxide 234 around the second channel region 232 and in contact with a second interconnect layer 220e of the second group of interconnect layers 220d-220f. The second channel section 200F can further include a fourth S/D region 236 over the second gate region and in contact with a third interconnect layer 220f of the second group of interconnect layers 220d-220f.

The channel structure 200G can further include a first dielectric layer 238 positioned between the top seed layer 214 and the first S/D region 222 of the first channel section 200E, a second dielectric layer 240 positioned between the second S/D region 228 of the first channel section 200E and the third S/D region 230 of the second channel section 200F, a third dielectric layer 242 positioned over the fourth S/D region 236 of the second channel section 200F, and an isolation structure 244 extending from the first dielectric layer 238 and further through the first channel section 200E, the second dielectric layer 240, the second channel section 200F, and the third dielectric layer 242.

The first transistor stack 200C can further include a cap layer 246 over the fourth S/D region 236. In some embodiments, the first S/D region 222, the first channel region 224, and the second S/D region 228 can be formed by a semiconductor material, such as Si, SiGe, Ge, or the like, and doped by a p-type dopant. Accordingly, the first channel section 200E and the first group of the interconnect layers 220a-220c can form a p-type transistor. The third S/D region 230, the second channel region 232, and the fourth S/D region 236 can be formed by a semiconductor material doped by a n-type dopant. Accordingly, the second channel section 200F and the second group of the interconnect layers 220d-220f can form a n-type transistor.

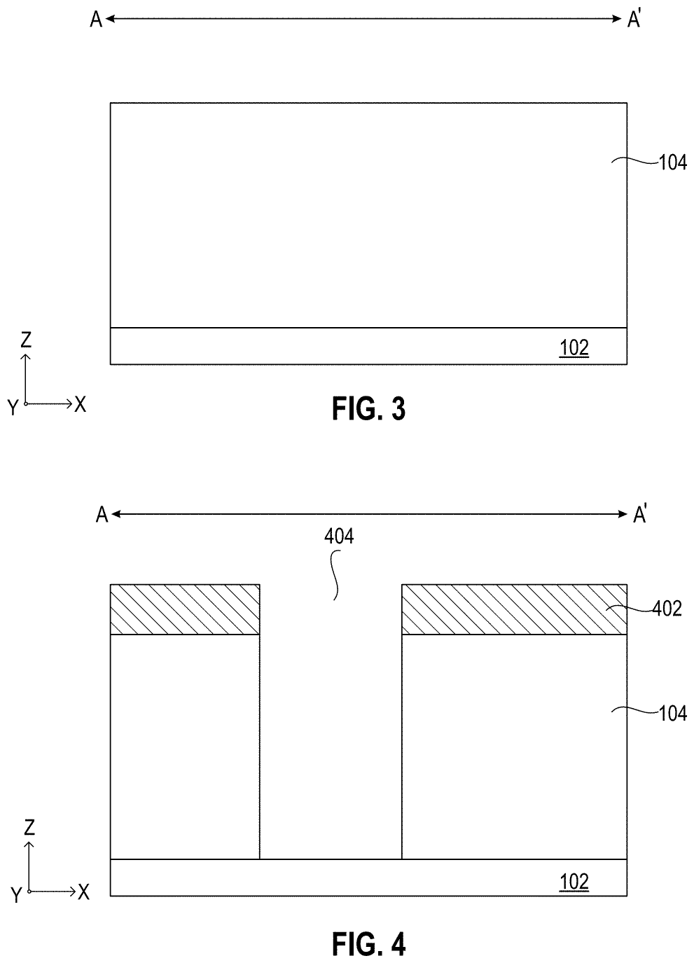

FIGS. 3-43 are top-down views and cross-sectional views of various intermediate steps in a manufacturing flow to fabricate the device 100 and the device 200, in accordance with some embodiments. As shown in FIG. 3, a dielectric layer 104 can be formed over a substrate 102. In some embodiments, the dielectric layer 104 can be a single layer. In some embodiments, the dielectric layer 104 can be a stack and include two or more layers. The dielectric layer 104 can include SiO, SiN, SiON, SiC, SiOC, SiCN, SiOCN, the like, or a combination thereof. The dielectric layer 104 can be formed by any suitable deposition techniques, such as a chemical vapor deposition (CVD) process, an atomic layer deposition (ALD) process, a diffusion process, or the like.

In FIG. 4, a mask layer 402 with patterns can be formed over the dielectric layer 104 based on a photolithographic process. An etching process can subsequently be applied to transfer the patterns of the mask layer 402 into the dielectric layer 104 to form openings. For example, an opening 404 can be illustrated in FIG. 4.

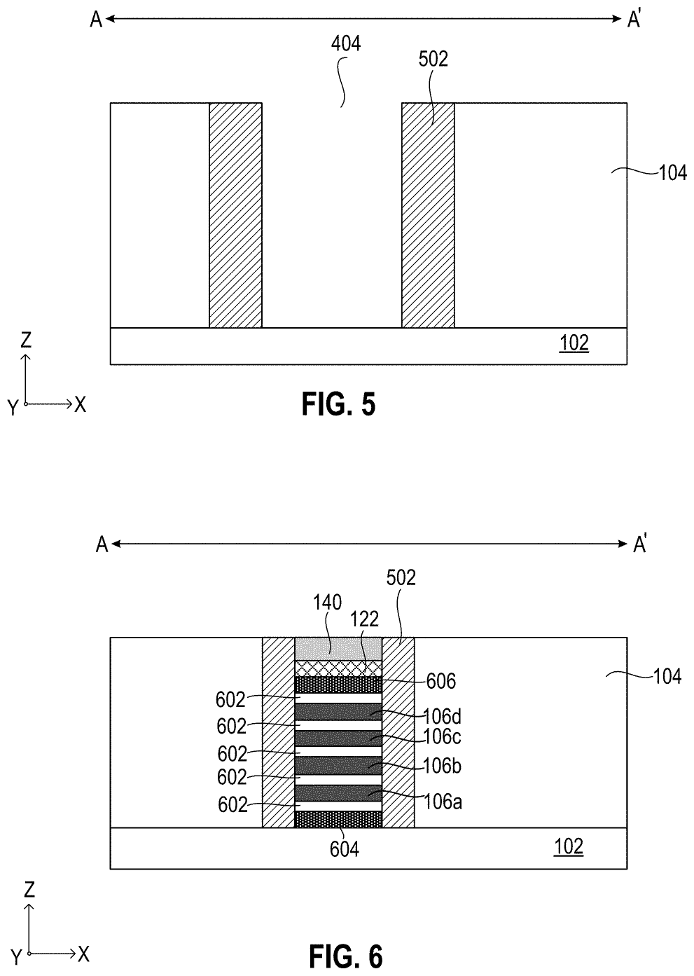

In FIG. 5, a spacer 502 can be formed along sidewalls of the opening 404. The spacer 502 can be made of a dielectric material, such as SiO, SiN, SiON, SiC, or like. In some embodiments, the dielectric material can further be deposited on the substrate 102 through the opening 404. Thus, a directional etching process can subsequently be applied to remove the dielectric material on the substrate 102, and the dielectric material formed along the sidewalls of the opening 404 can still remain to form the spacer 502.

In FIG. 6, a first transition layer 604 can be formed in the opening 404. The first transition layer 604 can be arranged over the substrate 102 and in contact with the spacer 502. A stack of channel layers 106a-106d and intermediate layers 602 can be alternatingly formed over the first transition layer 604. Further, a second transition layer 606 can be formed over the stack of channel layers 106a-106d and intermediate layers 602, a seed layer 122 can be formed over the second transition layer 606, and a cap layer 140 can be formed over the seed layer 122. In some embodiments, the cap layer 140 can include SiO, SiN, SiON, SiC, or like. The channel layers 106a-106d, the intermediate layers 602, the first transition layer 604, and the second transition layer 606 can include Si, SiG, Ge, or other suitable semiconductor materials. In an exemplary embodiment of FIG. 6, the channel layers 106a-106d can be made of Si, the intermediate layers 602 can be made of SiGe, and the first and second transition layers 604 and 606 can be made of SiGe that has a different Ge content from the intermediate layers 602.

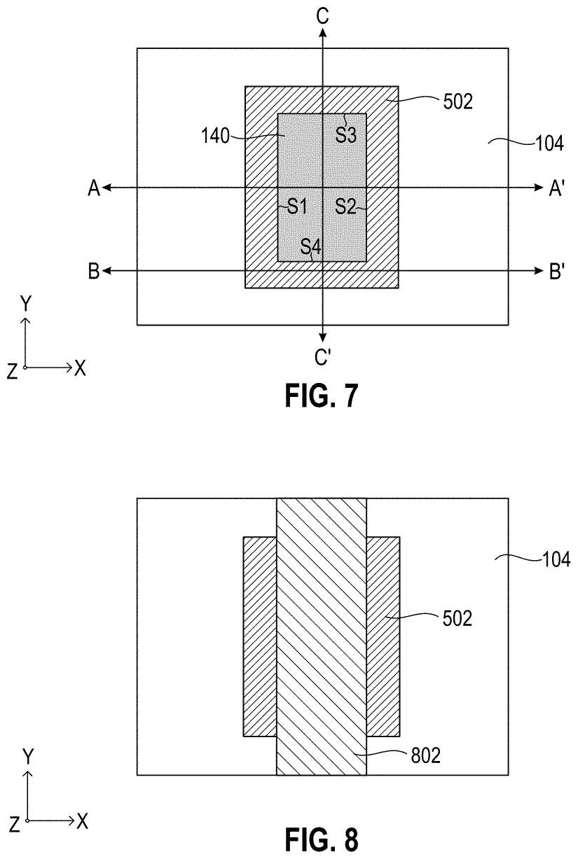

FIG. 7 is a top-down view of FIG. 6 when the cap layer 140 is formed. As shown, the cap layer 140 can be surrounded by the spacer 502. In some embodiments, the cap layer 140 and the stack of channel layers 106a-106d and intermediate layers 602 can have a quadrilateral shape that includes the first, second, third, and fourth sides S1-S4. In addition, three cross-sectional directions A-A′, B-B′, and C-C′ are provided, which can be applied in subsequent cross-sectional views.

In FIG. 8, a mask layer 802 can be formed to cover the cap layer 140. The mask layer 802 can further extend along a horizontal direction (e.g., Y direction) parallel to the substrate 102 to cover portions of the spacer 502 that are formed along the third side S3 and the fourth side S4 of the stack of channel layers 106a-106d and intermediate layers 602. The mask layer 802 can be a photoresist layer that is formed based on a photolithography process.

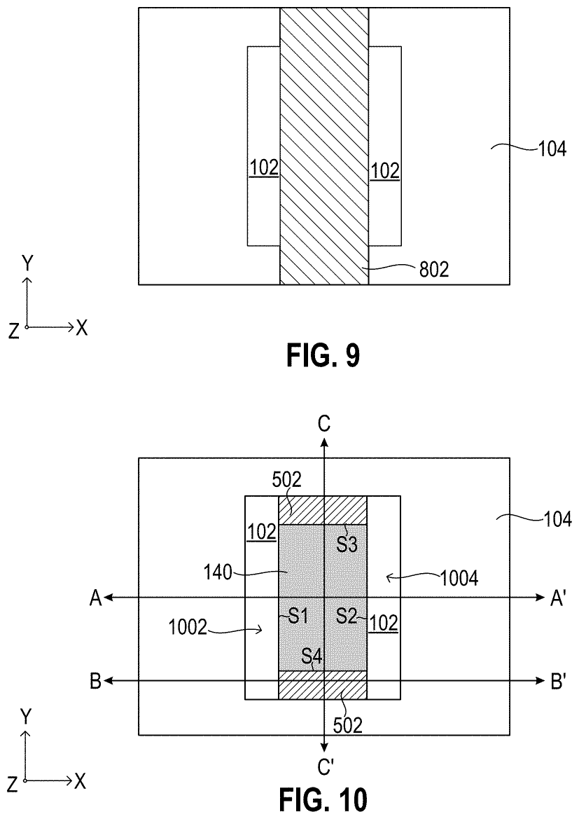

In FIG. 9, an etching process can be applied to remove portions of the spacer 502 that are formed along the first side 51 and the second side S2 of the stack of channel layers 106a-106d and intermediate layers 602. Accordingly, the substrate 102 can be uncovered by the etching process.

In FIG. 10, the mask layer 802 can be removed by a plasma ashing process. As shown in FIG. 10, spaces 1002 and 1004 can be formed when the portions of the spacer 502 that are adjacent to the first side Si and the second side S2 of the stack of channel layers 106a-106d and intermediate layers 602 are removed. The substrate 102 can be uncovered in the spaces 1002 and 1004.

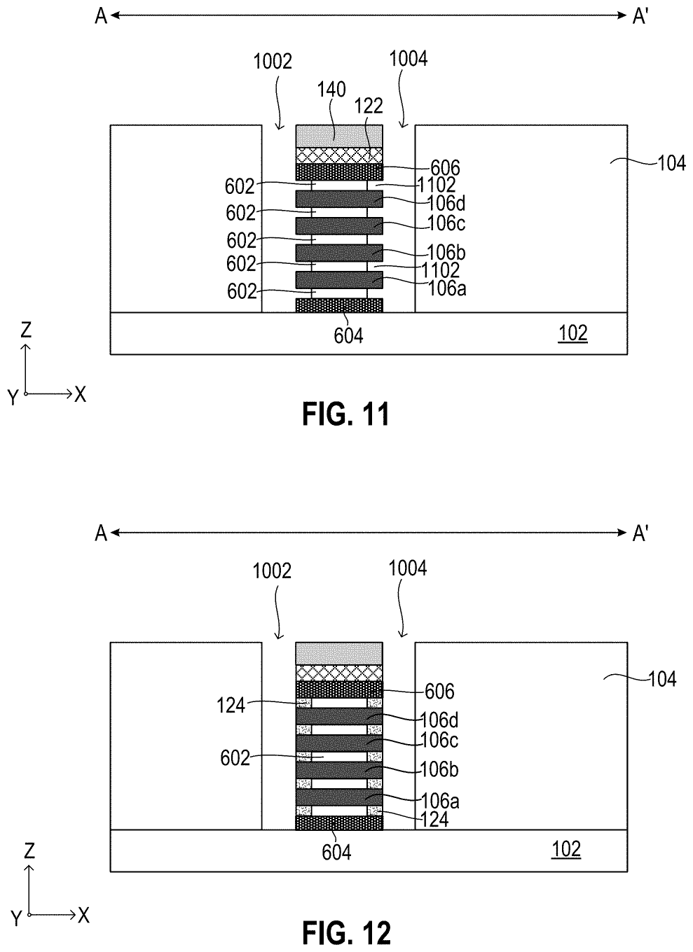

In FIG. 11, the intermediate layers 602 can be recessed through a selective etching process, where the selective etching can remove portions of the intermediate layers from the first side S1 and the second side S2 of the stack of channel layers 106a-106d and intermediate layers 602, and the channel layers 106a-106d are not impacted. Accordingly, spaces 1102 can be formed between the first transition layer 604, the channel layers 106a-106d, and the second transition layer 606. It should be noted that FIG. 11 is a cross-sectional view that is obtained from a same plane as a vertical plane along line A-A′ in FIG. 10.

In FIG. 12, insulating layers 124 can be formed on surfaces of the channel layers 106a-106d and arranged between the first transition layer 604, the channel layers 106a-106d, and the second transition layer 606. Accordingly, the intermediate layers 602 can be disposed between the insulating layers 124. The insulating layer 124 can be made of any suitable dielectric material, such as SiN, SiO, SiCN, SiC, or the like. The insulating layers 124 can be formed by any suitable deposition process, such as a CVD process, an ALD process, and a diffusion process.

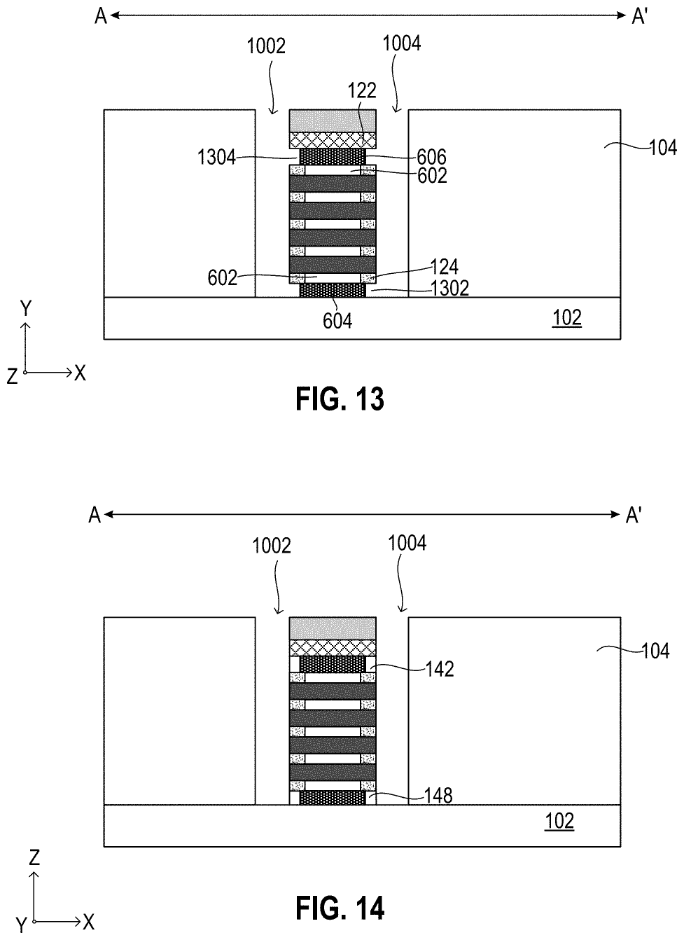

In FIG. 13, the first transition layers 604 and the second transition layer 606 can be recessed through a selective etching process. The selective etching process can introduce an etching plasma through the spaces 1002 and 1004 to remove portions of the first transition layers 604 and the second transition layer 606 from the first side Si and the second side S2 of the stack of channel layers 106a-106d and intermediate layers 602. Accordingly, a space 1302 can be formed between a lowermost insulating layer of the insulating layers 124 and the substrate 102, and a space 1304 can be formed between an uppermost insulating layer of the insulating layers 124 and the seed layer 122.

In FIG. 14, top dielectric layers 142 can be formed in the space 1304 and bottom dielectric layers 148 can be formed in the space 1302. In order to form the top dielectric layers 142 and the bottom dielectric layers 148, a selective deposition process can be applied to deposit a dielectric material in the spaces 1302 and 1304. The top dielectric layers 142 and the bottom dielectric layers 148 can include SiO, SiN, SiON, SiC, or the like.

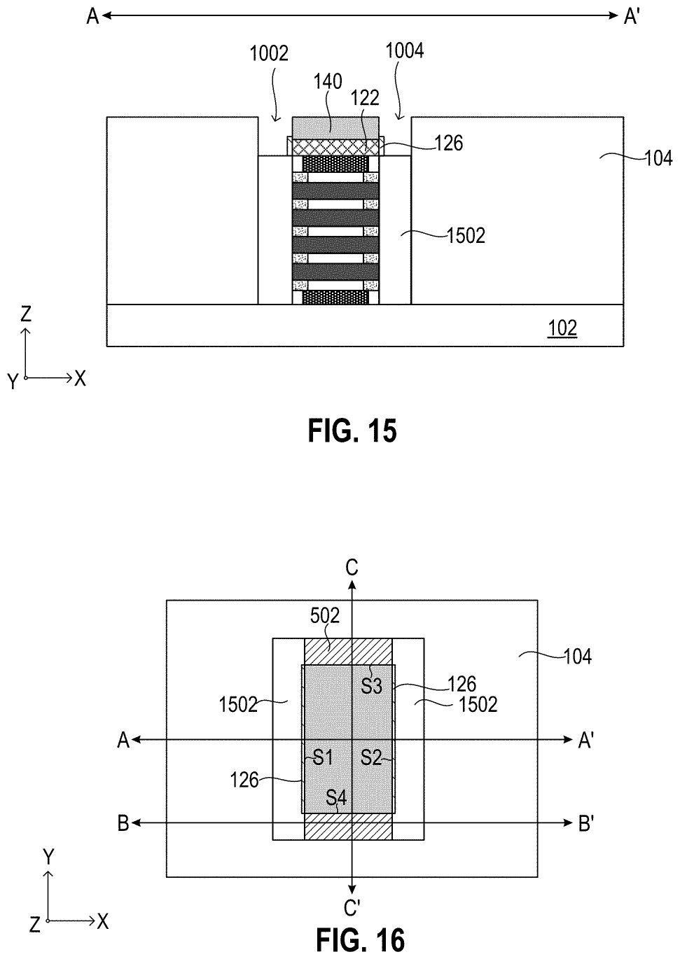

In FIG. 15, dielectric layers 1502 can be deposited to fill in the spaces 1002 and 1004. The dielectric layers 1502 can then be recessed to uncover the seed layer 122. A high-k layer 126 can further be disposed along sidewalls of the seed layer 122. The high-k layer 126 can be one of HfO₂, ZrO₂, HfSiNO₂, ZrSiNO₂, Y₃O₄, Si₃N₄, and Al₂O₃.

FIG. 16 shows a top down view when the high-k layer 126 is formed. As shown, the dielectric layer 1502 can be formed in the spaces 1002 and 1004 such that the stack of channel layers 106a-106d and intermediate layers 602 are arranged between the dielectric layers 1502. The high-k layer 126 can be formed along sidewalls of the seed layer 122 and positioned at the first side Si and the second side S2 of the stack of channel layers 106a-106d and intermediate layers 602.

In FIG. 17, the dielectric layers 1502 can be recessed to uncover the channel layers 106a-106d. In some embodiments, the dielectric layers 1502 can be recessed to have a height approximately equal to a height of the first transition layer 604. The remaining dielectric layers 1502 can become the a first dielectric layer 128 positioned over the substrate 102 and along the first side S1 of the stack of channel layers 106a-106d and intermediate layers 602, and a second dielectric layer 130 positioned over the substrate 102 and adjacent to the second side S2 of the stack of channel layers 106a-106d and intermediate layers 602. Further, a space 1702 can be formed at the first side S1 of the stack of channel layers 106a-106d and intermediate layers 602, and a space 1704 can be formed at the second side S2 of the stack of channel layers 106a-106d and intermediate layers 602.

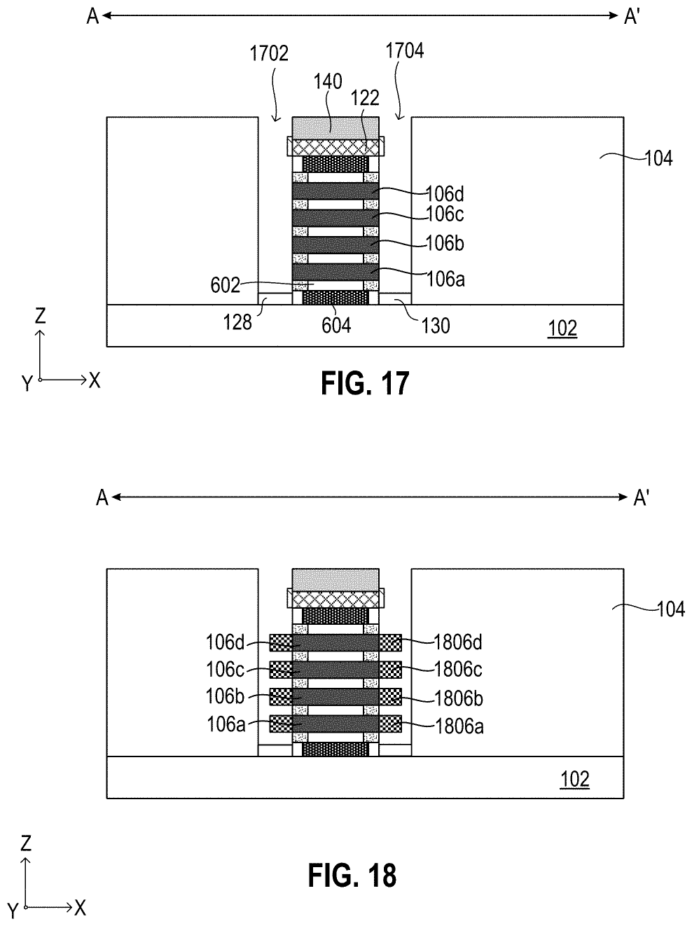

FIG. 18 shows a first exemplary embodiment of forming S/D structures 1806a-1806d, where the S/D structures 1806a-1806d can be formed at two sides of the channel layers 106a-106d respectively. The S/D structures 1806a-1806d can be arranged at the first side S1 and the second side S2 of the stack of channel layers 106a-106d and intermediate layers 602, and spaced apart from one another.

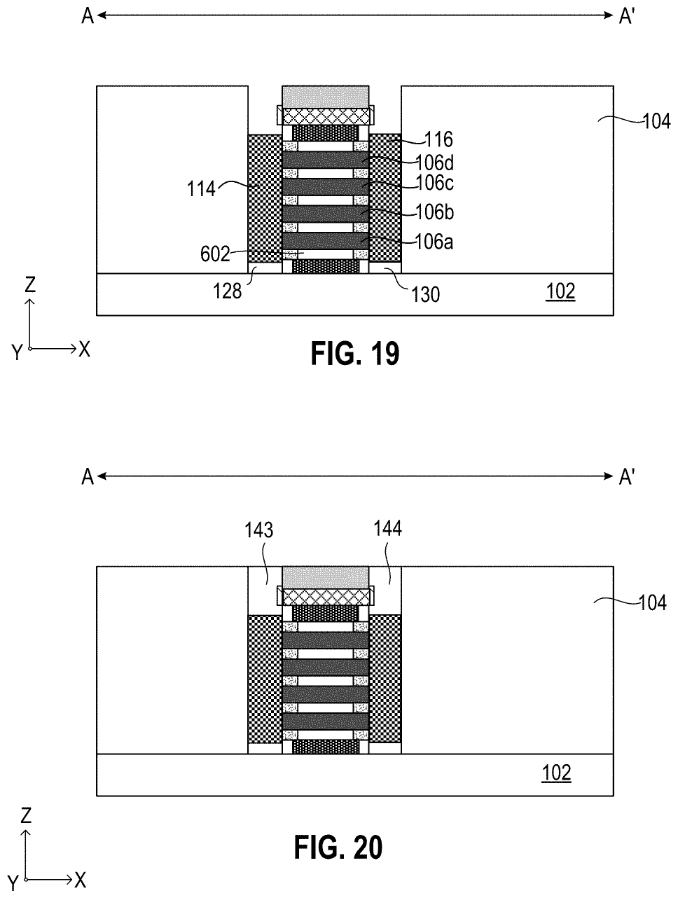

FIG. 19 shows a second exemplary embodiment of forming a first S/D structure 114 and a second S/D structure 116, where the first S/D structure 114 can be positioned at the first side S1 of the stack of channel layers 106a-106b and intermediate layers 602, and the second S/D structure 116 can be positioned at the second side S2 of the stack of channel layers 106a-106d and intermediate layers 602. The first and second S/D structures 114 and 116 can be in contact with the channel layers 106a-106d such that the channel layers 106a-106b are arranged between the first S/D structure 114 and the second S/D structure 116. In addition, the channel layers 106a-106d can be coupled to each other based on the first S/D structure 114 and the second S/D structure 116.

In FIG. 20, a structure 143 can be positioned over the first S/D structure 114 at the first side S1 of the stack of channel layers 106a-106d and intermediate layers 602, and a structure 144 can be positioned over the second S/D structure 116 at the second side S2 of the stack of channel layers 106a-106d and intermediate layers 602. In some embodiments, the structures 143-144 can be made of a dielectric material, such as SiO, SiN, SiON, SiC, the like, or a combination thereof. In some embodiments, the structures 143-144 can be made of a conductive material, such as W, Co, Ru, Cu, Al, or the like, and function as interconnect structures.

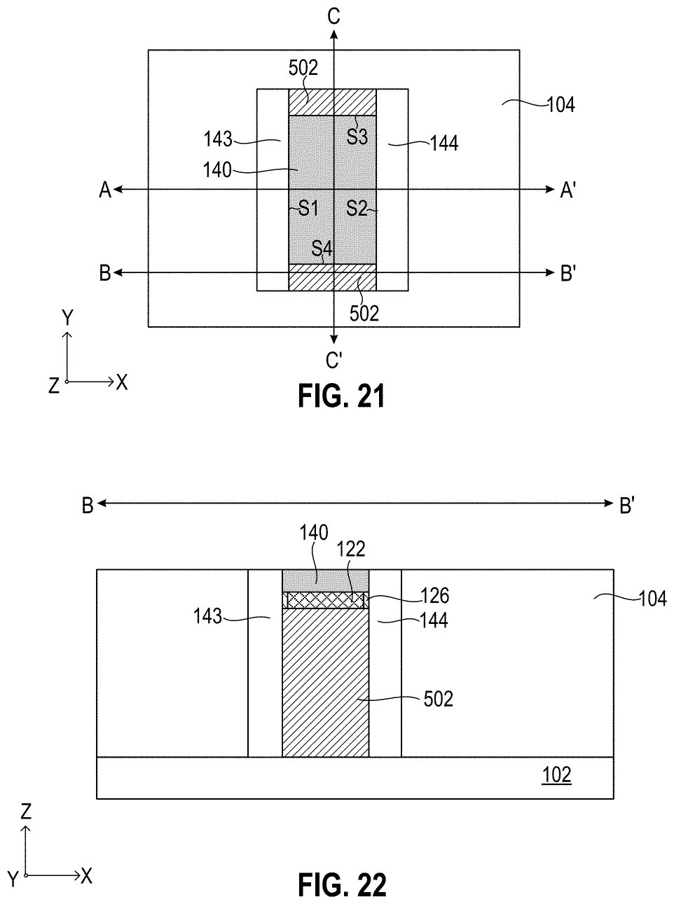

FIG. 21 shows a top down view of the structures 143 and 144. As shown in FIG. 21, the structure 143 is positioned at the first side S1 of the stack of channel layers 106a-106d and intermediate layers 602, and the structure 144 is positioned at the second side S2 of the stack of channel layers 106a-106d and intermediate layers 602. In addition, the spacer 502 is arranged at the third side S3 and the fourth side S4 of the stack of channel layers 106a-106d and intermediate layers 602.

In FIG. 22, the spacer 502 can be recessed by a selective etching process along a direction (e.g., Z direction) perpendicular to the substrate 102. Accordingly, the cap layer 140, the seed layer 122, and the high-k layer 126 can be uncovered by the selective etching process. The structures 143 and 144 are not affected by the selective etching process. The cross-sectional view of FIG. 22 is obtained from a same plane as a vertical plane along line B-B′ in FIG. 21.

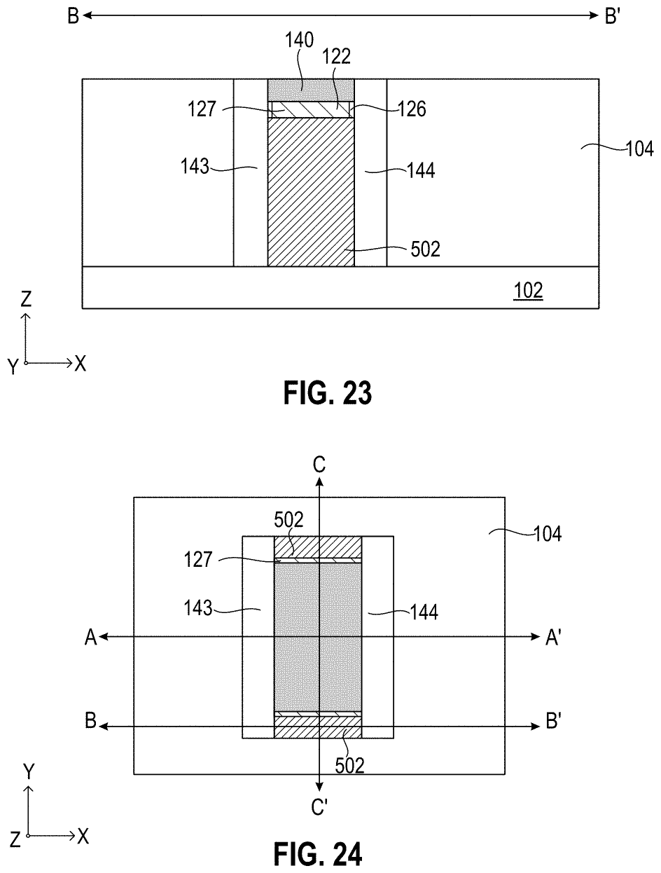

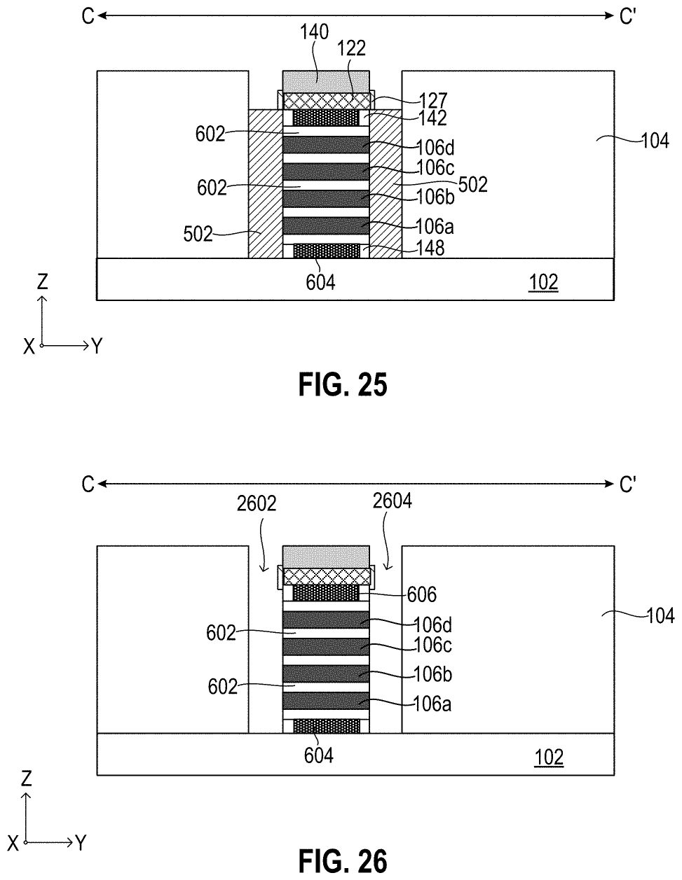

In FIG. 23, a high-k layer 127 can be formed along sidewalls of the seed layer 122 and positioned at the third side S3 and the fourth side S4 of the stack of channel layers 106a-106d and intermediate layers 602. Accordingly, the seed layer can be surrounded by the high-k layers 126 and 127. FIG. 24 is a top down view when the high-k layer 127 is formed. FIG. 25 is a cross-sectional view when the high-k layer 127 is formed. The cross-sectional view of FIG. 25 is obtained from a same plane as a vertical plane along line C-C′ in FIG. 24.

In FIG. 26, the spacer 502 can be removed by an etching process. Accordingly, spaces 2602 and 2604 can be formed along the third side S3 and the fourth side S4 of the stack of channel layers 106a-106d and intermediate layers 602. The channel layers 106a-106d and the intermediate layers 602 can be uncovered by the spaces 2602 and 2604.

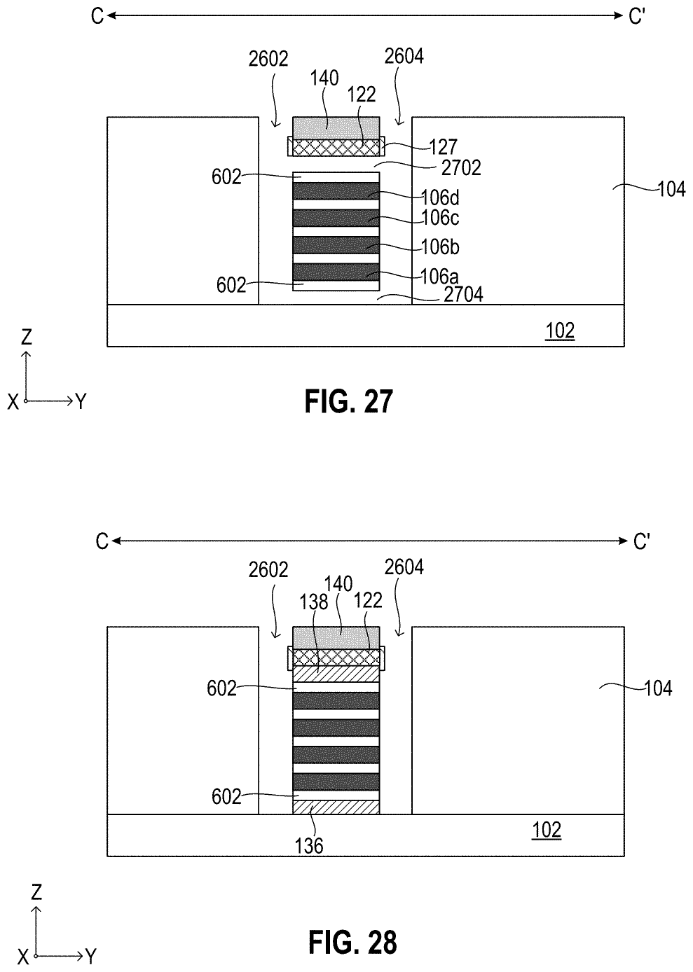

In FIG. 27, the first transition layer 604 and the second transition layer 606 can be removed through a selective etching process, where the seed layer 122, the channel layers 106a-106d, and the intermediate layers 602 are not impacted by the selective etching process. Accordingly, a space 2702 can be formed between the seed layer 122 and the uppermost channel layer 106d, and a space 2704 can be formed between the substrate 102 and the lowermost intermediate layer 602.

In FIG. 28, a dielectric material can be deposited in the spaces 2702 and 2704 to form a first isolation layer 136 and a second isolation layer 138 respectively. As shown in FIG. 28, the first isolation layer 136 can be formed between the lowermost intermediate layer 602 and the substrate 102, and the second isolation layer 138 can be formed between the uppermost intermediate layer 602 and the seed layer 122.

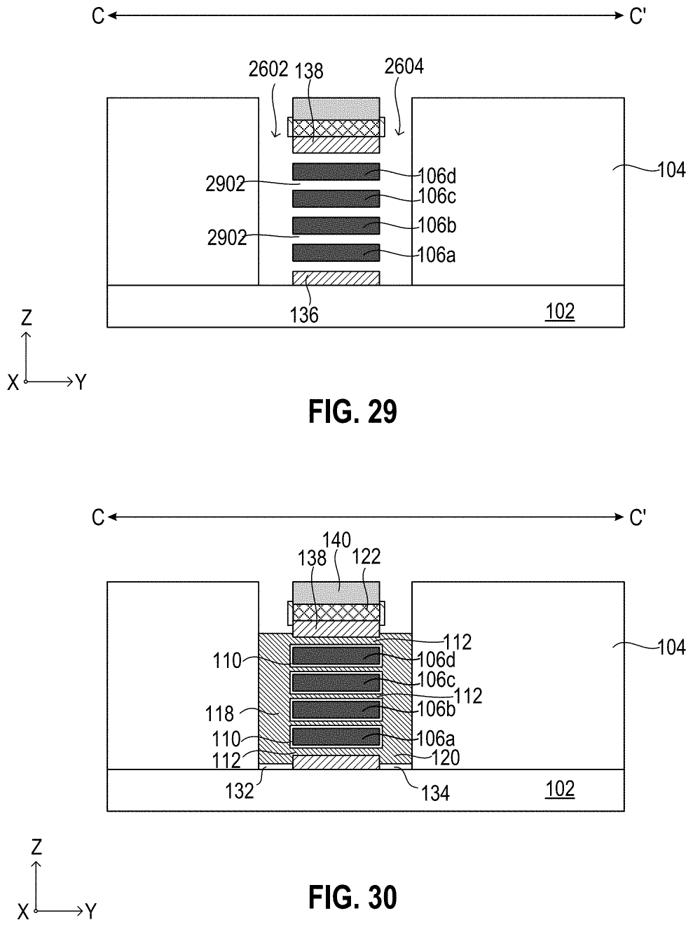

In FIG. 29, the intermediate layers 602 can be removed by a selective etching process, and the channel layers 106a-106d can still remain. Accordingly, spaces 2902 can be formed between the first isolation layer 136 and the uppermost channel layer 106d, between the channel layers 106d-106a, and between the lowermost channel layer 106a and the substrate 102.

In FIG. 30, gate dielectric layers 110 can be formed on the surfaces of the channel layers 106a-106d. In some embodiments, the gate dielectric layers 110 can be made of a high-k material. In order to form the gate dielectric layers 110, a selective deposition process can be applied to deposit the high-k material on the surfaces of the channel layers 106a-106d. The high-k material can also be formed over the substrate 102 to form a first high-k layer 132 and a second high-k layer 134 over the substrate 102. The first high-k layer 132 can be formed at the third side S3 of the stack of channel layers 106a-106d and the second high-k layer 134 can be formed at the fourth side S4 of the stack of channel layers 106a-106d. Further, a gate material can be deposited in the spaces 2902 to form gate electrode layers 112. The gate material can also be deposited in the spaces 2602 and 2604 and over the first and second high-k layers 132 and 143 to form a first gate electrode 118 positioned at the third side S3 of the stack of channel layers 106a-106d and over the first high-k layer 132, and a second gate electrode 120 positioned at the fourth side S4 of the stack of channel layers 106a-106d and over the second high-k layer 134. The gate material can include a work function layer (e.g., TiON or TiC), a liner (e.g., TiN or TaN), and a filler (e.g., W or Ru).

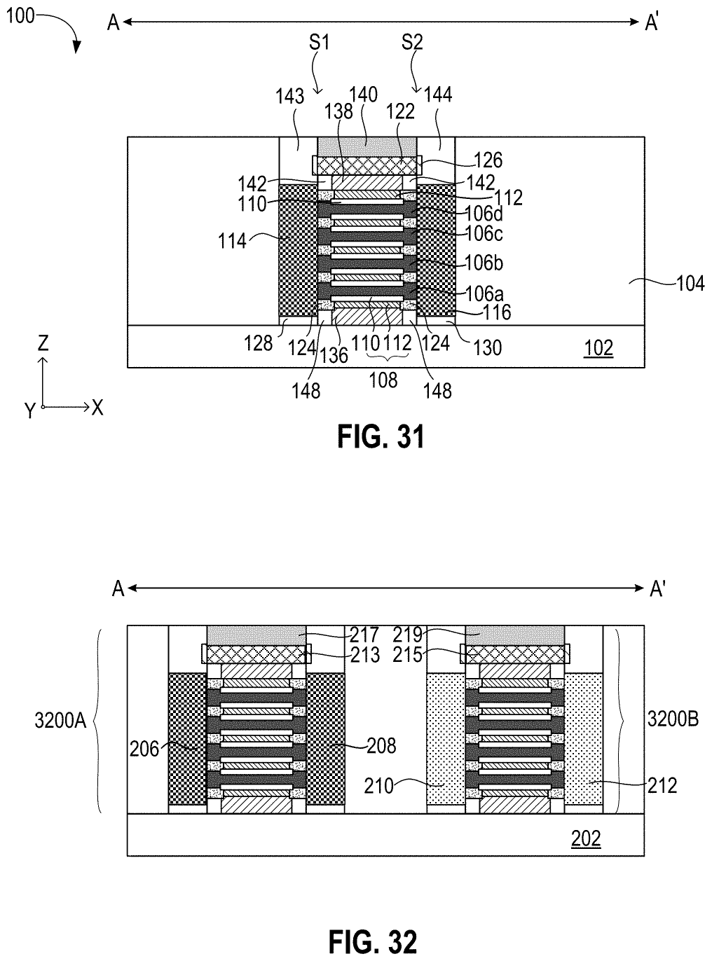

When the gate dielectric layers 110, the gate electrode layers 112, and the first and second gate electrodes 118 and 120 are formed, a device 100 can be formed. FIG. 31 shows a cross-sectional view of the device 100 that is obtained from a same plane as a vertical plane along line A-A′ in FIG. 24. As shown in FIG. 31, the device 100 in FIG. 31 can have identical features to the device 100 shown in FIG. 1B.

FIG. 32 shows a n-type transistor 3200A and a p-type transistor 3200B that are formed over a substrate 202. The n-type transistor 3200A can have similar features to the n-type transistor 200A in FIG. 2, and the p-type transistor 3200B can have similar features to the p-type transistor 200B in FIG. 2. The difference between the n-type transistor 3200A and the n-type transistor 200A is that the n-type transistor 3200A can have a cap layer 217 and the n-type transistor 200A can have a top seed layer 214 over the seed layer 213. The difference between the p-type transistor 3200B and the p-type transistor 200b is that the p-type transistor 3200B can have a cap layer 219 and the p-type transistor 200B can have a top seed layer 216 over the seed layer 215. The n-type transistor 3200A and the p-type transistor 3200B can be formed based on manufacturing processes similar to the manufacturing processes illustrated in FIGS. 3-31.

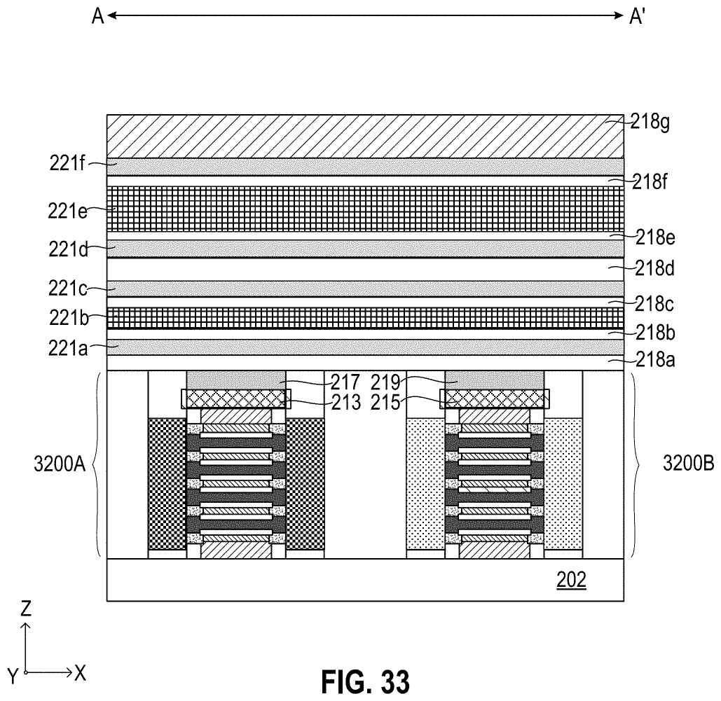

In FIG. 33, a stack of alternating insulating layers 218a-218g and interconnect layers 221a-221f can be formed over the n-type transistor 3200A and the p-type transistor 3200B. The insulating layers 218a-218b can be made of a dielectric material, such as SiO or SiN. The interconnect layers 221a, 221c, 221d, and 221f can be made of a conductive material, such as W or polysilicon. The interconnect layers 221b and 221e can be made of a dielectric material, and function as dummy interconnect layers.

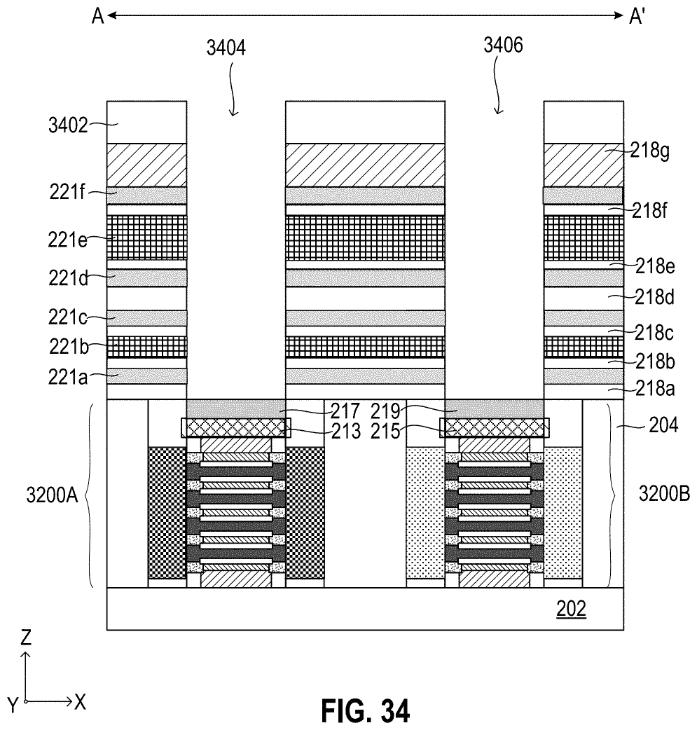

In FIG. 34, a mask layer 3402 with patterns can be formed over the insulating layer 218g through a photolithography process. An etching process can subsequently be applied to transfer the patterns into the insulating layer 218a-218g and the interconnect layers 221a-221f to form openings 3404 and 3406. The opening 3404 can uncover the cap layer 217 in the n-type transistor 3200A, and the opening 3406 can uncover the cap layer 219 in the p-type transistor 3200B.

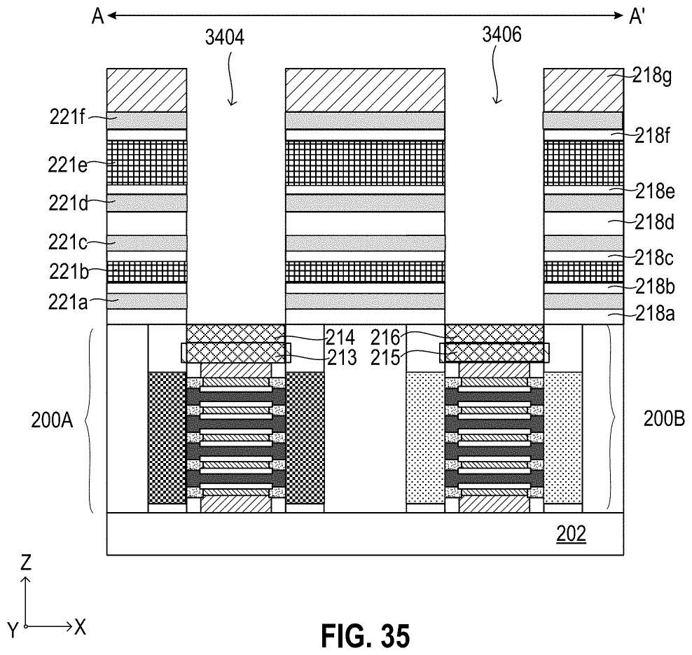

In FIG. 35, the cap layers 217 and 219 can be removed by an etching process. The mask layer 3402 can be removed. A top seed layer 214 can subsequently be formed on the seed layer 213, and a top seed layer 216 can subsequently be formed on the seed layer 215. Accordingly, the n-type transistor 3200A can become 200A, and the p-type transistor 3200B can become 200B. The top seed layers 214 and 216 can be made of any suitable semiconductor materials, such as Si, SiGe, Ge, SiC, or the like. The top seed layers 214 and 216 can be formed through any suitable deposition processes, such as an epitaxial deposition process.

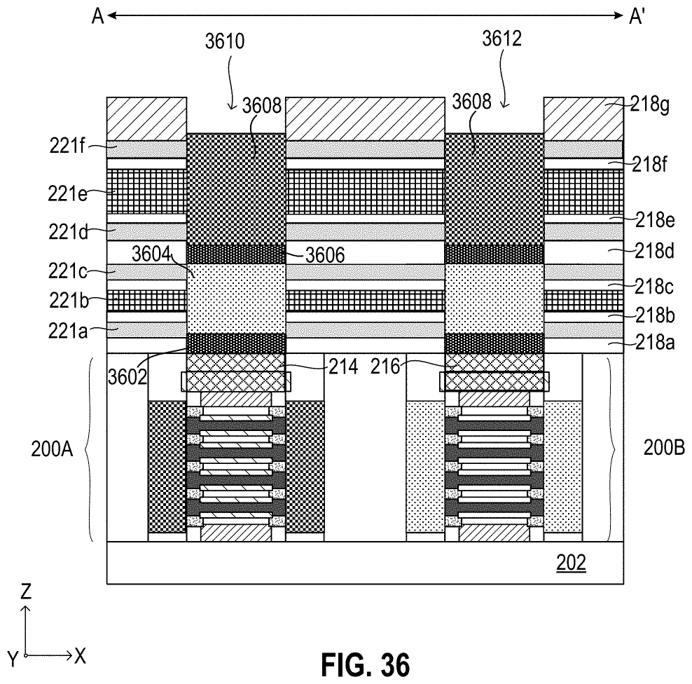

In FIG. 36, a first stack structure 3610 can be formed in the opening 3404 and a second stack structure 3612 can be formed in the opening 3406. For simplicity and clarity, features of the first stack structure 3610 and the second stack structure 3612 can be described based on the first stack structure 3601. As shown in FIG. 36, the first stack structure 3610 can include a first dummy layer 3602 on the top seed layer 214, a first semiconductor layer 3604 on the first dummy layer 3602, a second dummy layer 3606 on the first semiconductor layer 3604, and a second semiconductor layer 3608 on the second dummy layer 3606. In some embodiments, the first dummy layer 3602 and the second dummy layer 3606 can be made of SiGe. The first semiconductor layer 3604 can be formed based on Si, SiGe, Ge, or other suitable semiconductor material, and doped with a p-type dopant. The second semiconductor layer 3608 can be formed based on Si, SiGe, Ge, or other suitable semiconductor material, and doped with a n-type dopant. Of course, the first semiconductor layer 3604 can be doped with a n-type dopant and the second semiconductor layer 3608 can be doped with a p-type dopant. It should be noted that the first semiconductor layer 3604 is in contact with the interconnect layers 221a-221c, and the second semiconductor layer 3608 is in contact with the interconnect layers 221d-221f.

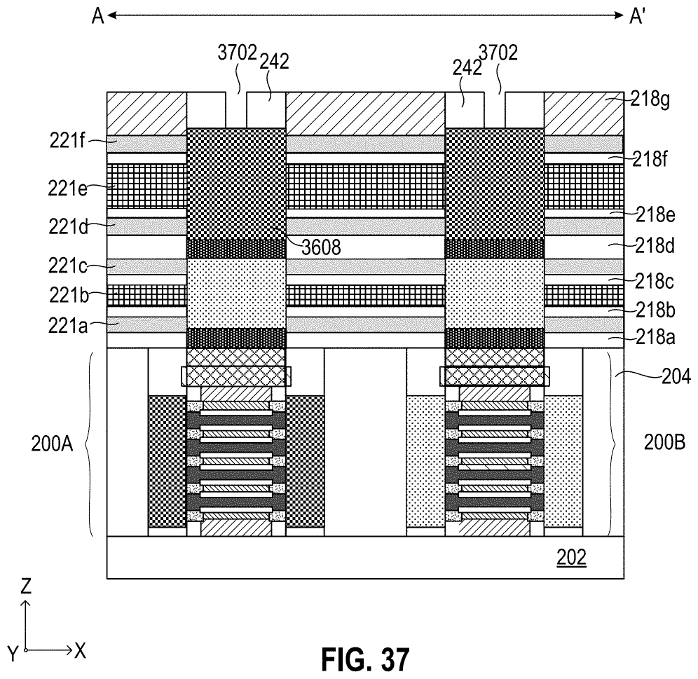

In FIG. 37, a dielectric layer 242 can be formed over the second semiconductor layer 3608. Further, patterns 3702 can be formed in the dielectric layer 242 to uncover the second semiconductor layer 3608.

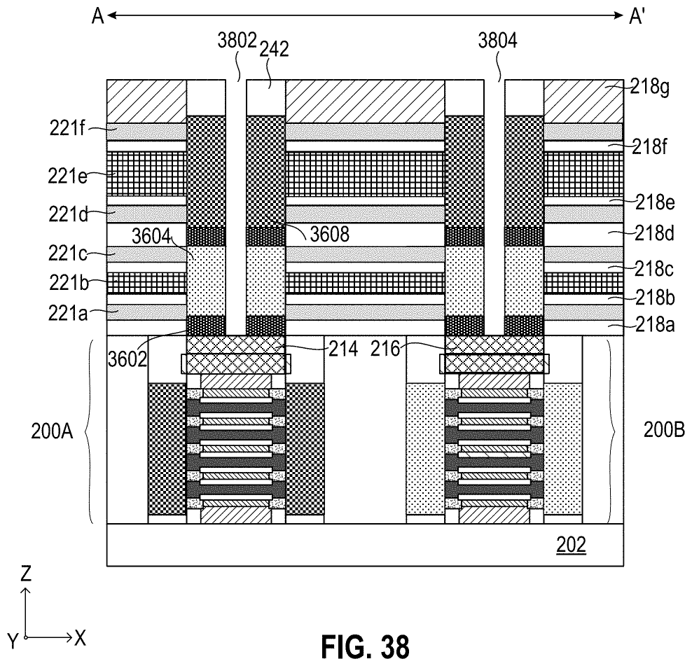

In FIG. 38, the dielectric layer 242 can function as a mask layer and a directional etching process can be applied based on the mask layer to etch through the second semiconductor layer 3608, the second dummy layer 3606, the first semiconductor layer 3604, and the first dummy layer 3602. Accordingly, openings 3802 and 3804 can be formed to uncover the top seed layers 214 and 216 respectively.

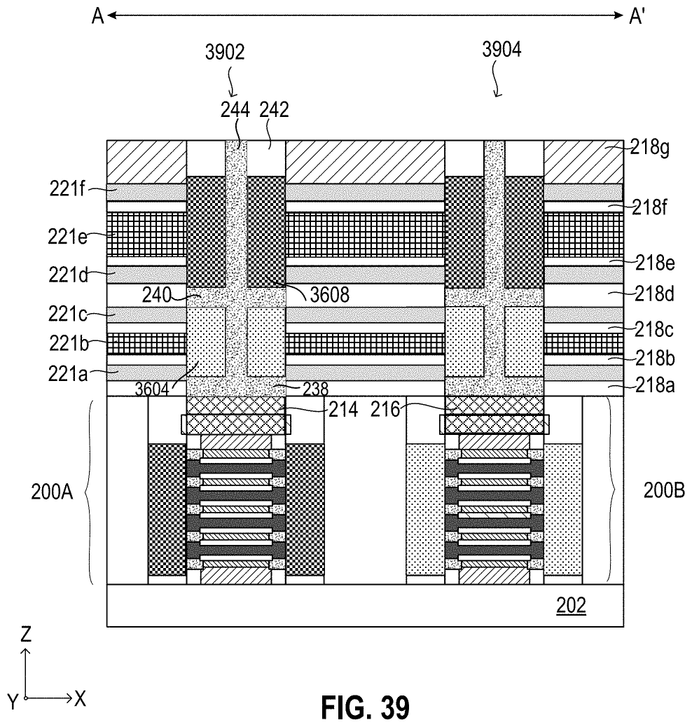

In FIG. 39, the first dummy layer 3602 and the second dummy layer 3606 can be removed to form spaces (not shown) between the top seed layers (e.g., 214 and 216) and the first semiconductor layer 3604, and between the first semiconductor layer 3604 and the second semiconductor layer 3608. A dielectric material can be subsequently deposited into the spaces and the openings 3802 and 3804. Accordingly, a first channel structure 3902 can be formed based on the first stack structure 3610 and a second channel structure 3904 can be formed based on the second stack structure 3612. For simplicity and clarity, the features of the first channel structure 3902 and the second channel structure 3904 can be described based on the first channel structure 3902. As shown in FIG. 39, the first channel structure can include a first dielectric layer 238 between the top seed layer 214 and the first semiconductor layer 3604, a second dielectric layer 240 between the first semiconductor layer 3604 and the second semiconductor layer 3608, the dielectric layer 242 which can be a third dielectric layer 242, and an isolation structure 244 extending through the third dielectric layer 242, the second semiconductor layer 3608, the second dielectric layer 240, the first semiconductor layer 3604, and the first dielectric layer 238.

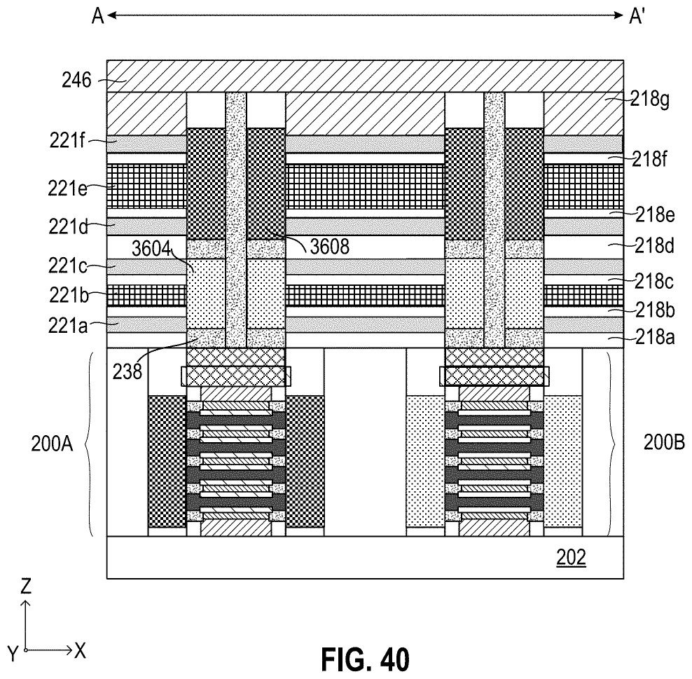

In FIG. 40, a cap layer 246 can be formed over the insulating layer 218g. The cap layer 246 can be made of a dielectric material, such as SiO, SiN, SiN, SiCN, or the like.

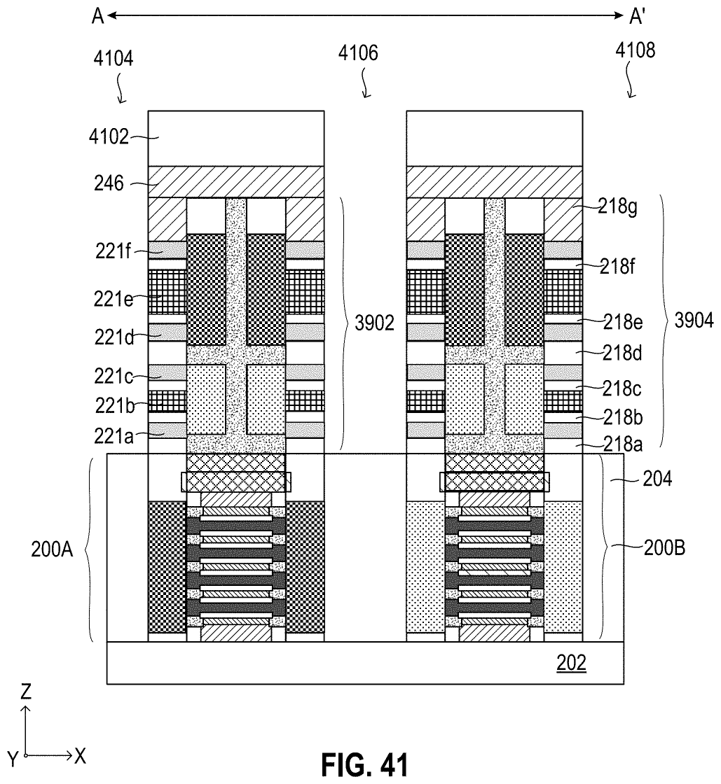

In FIG. 41, a mask layer 4102 with patterns can be applied based on a photolithographic process. An etching process can subsequently be applied to etch through the cap layer 246 and the stack of insulating layers 218a-218g and interconnect layers 221a-221f based on the patterns of the mask layer 4102. When the etching process is completed, the first channel structure 3902 and the second channel structure 3904 can be spaced apart from each other by gaps 4104, 4106, and 4108.

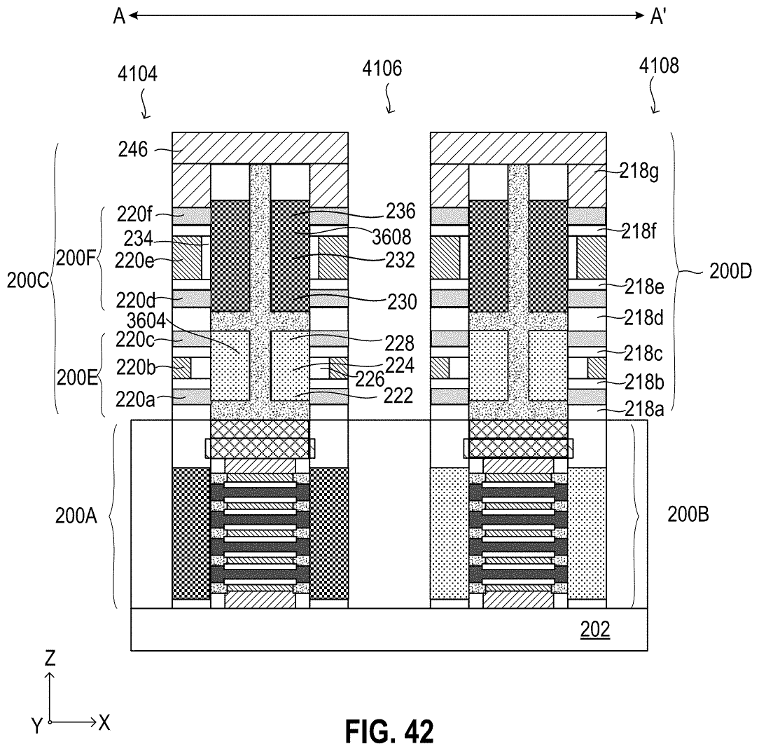

In FIG. 42, the mask layer 4102 can be removed by an etching process or a dry ashing process. Further, the interconnect layer 221b can be replaced by a gate oxide 226 and an interconnect layer 220b, where the gate oxide 226 is disposed around the first semiconductor layer 3604 and the interconnect layer 220b is disposed around the gate oxide 226. The interconnect 221e can be replaced by a gate oxide 234 and an interconnect layer 220e, where the gate oxide 234 is disposed around the second semiconductor layer 3608 and the interconnect layer 220e is disposed around the gate oxide 234. The interconnect layers 220b and 220e can be made of a conductive material. When the gate oxide 226, the interconnect layer 220b, the gate oxide 234, and the interconnect layer 220e are formed, the interconnect layers 221a, 221c-221d, and 221f can be labeled as 220a, 220a-220d, and 220f respectively. The gate oxides 226 and 234, and the interconnect layers 220a-220f can be identical to the gate oxides 226 and 234, and the interconnect layers 220a-220f shown in FIG. 2.

Still referring to FIG. 42, a first transistor stack 200C can be formed based on the first channel structure 3902, and a second transistor stack 200D can be formed based on the second channel structure 3904. The first transistor stack 200C can include a first channel section 200E positioned over the top seed layer 214 and coupled to the interconnect layers 220a-220c, and a second channel section 200F positioned over the first channel section 200E and coupled to the interconnect layers 220d-220f. The first channel section 200E can include a first S/D region 222 that is positioned over the top seed layer 214 and in contact with the interconnect layer 220a. The first channel section 200E can also include a first gate region over the first S/D region 222. The first gate region can include (i) a first channel region 224 over the first S/D region 222 and (ii) the gate oxide 226 around the first channel region 224 and in contact with the interconnect layer 220b. The first channel section 200E can include a second S/D region 228 over the first gate region and in contact with the interconnect layer 220c. The first S/D region 222, the first channel region 224, and the second S/D region 228 can be formed based on the first semiconductor layer 3604.

The second channel section 200F can include a third S/D region 230 over the second S/D region 228 and in contact with the interconnect layer 220d. The second channel section 200F can include a second gate region over the third S/D region 230. The second gate region can include (i) a second channel region 232 over the third S/D region 230 and (ii) the gate oxide 234 around the second channel region 232 and in contact with the interconnect layer 220e. The second channel section 200F can further include a fourth S/D region 236 over the second gate region and in contact with the interconnect layer 220f. The third S/D region 230, the second channel region 232, and the fourth S/D region 236 can be formed based on the second semiconductor layer 3608.

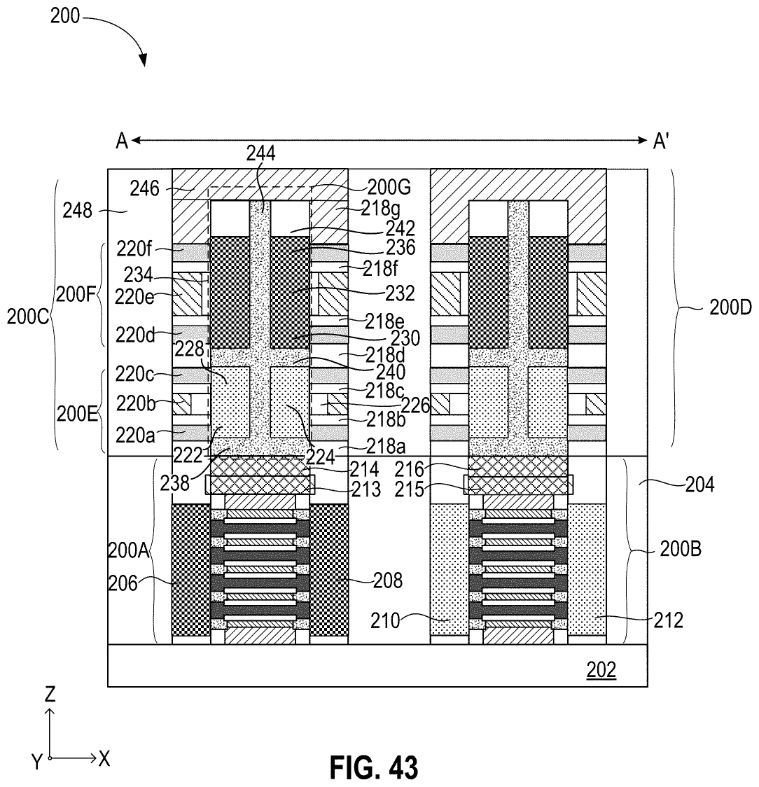

In FIG. 43, a dielectric layer 248 can be formed to fill in the gaps 4104, 4106, and 4108. Accordingly, a device 200 can be formed that can be identical to the device 200 in FIG. 2.

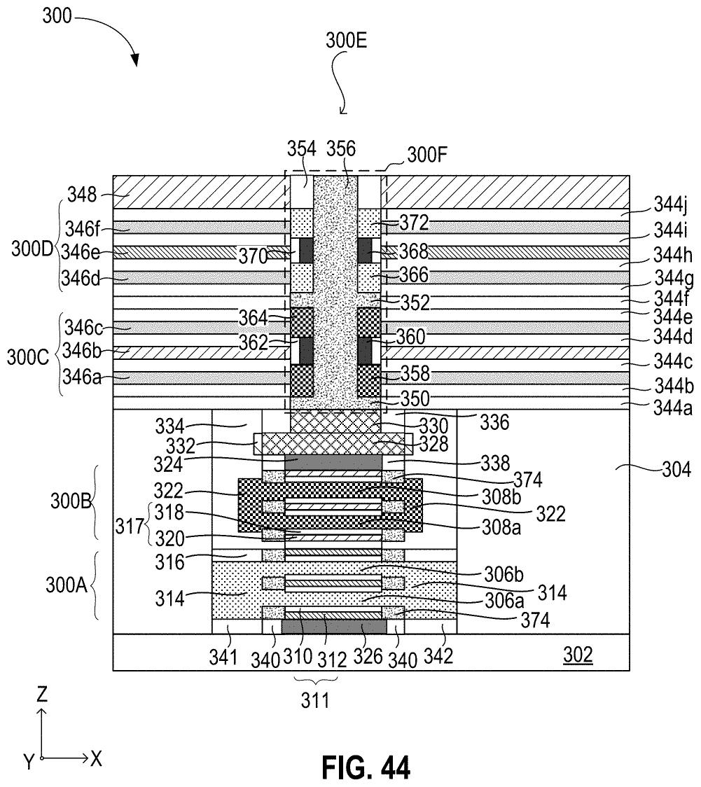

FIG. 44 shows a cross-sectional view a semiconductor device (or device) 300, in accordance with some embodiments. The device 300 can include a plurality of n-type channel layers and a plurality of p-type channel layers stacked over a substrate 302. In an embodiment, the n-type channel layers can be positioned over the p-type channel layers. In another embodiment, the p-type channel layers can be positioned over the n-type channel layers. For example, as shown in FIG. 44, a plurality of n-type channel layers 308a-308b and a plurality of p-type channel layers 306a-306b can be stacked over a substrate 302, where the n-type channel layers 308a-308b can be positioned over the p-type channel layer 306a-306b. The n-type channel layers 308a-308b can be made of a semiconductor material (e.g., Si, SiGe, Ge, or SiC) and doped with a n-type dopant. The p-type channel layers 306a-306b can be made of a semiconductor material (e.g., Si, SiGe, Ge, or SiC) and doped with a p-type dopant.

The device 300 can include a plurality of n-type gate structures 317 and a plurality of p-type gate structures 311. The n-types gate structures 317 can be positioned between the n-type channel layers 308a-308b and arranged on the surfaces of the n-type channel layers 308a-308b. The p-types gate structures 311 can be positioned between the p-type channel layers 306a-306b and arranged on the surfaces of the p-type channel layers 306a-306b. Each of the n-type gate structures 317 can further include a gate dielectric layer 318 positioned on the surfaces of the channel layers 308a-308b, and a gate electrode layer 320 formed along and in contact with the gate dielectric layer 318. In some embodiments, the gate dielectric layer 318 can include SiO₂, HfO₂, ZrO₂, HfSiNO₂, ZrSiNO₂, Y₃O₄, Si₃N₄, Al₂O₃, the like, or a combination thereof. The gate electrode layer 320 can include a work function layer (e.g., TiC, AlTiC, AlTiO), a liner (e.g., TiN), and a filler (e.g., W or Ru). Each of the p-type gate structures 311 can further include a gate dielectric layer 310 positioned on the surfaces of the channel layers 306a-306b, and a gate electrode layer 312 formed along and in contact with the gate dielectric layer 310. The gate electrode layer 312 can include a work function layer (e.g., TiON, TiC, AlTiN, AlTiC, AlTiO), a liner (e.g., TiN and/or TaN), and a filler (e.g., W or Ru).

The device 300 can further include n-type S/D structures 322 and p-type S/D structures 314 that are stacked over the substrate 302. The n-type channel layers 308a-308b can be positioned between and coupled to the n-type S/D structures 322, and the p-type channel layers 306a-306b can be positioned between and coupled to the p-type S/D structures 314. In some embodiments, the n-type S/D structures 322 can be made of silicon that is epitaxially deposited and doped with a n-type dopant, such as phosphorous. The p-type S/D structures 314 can be made of silicon that is epitaxially deposited and doped with a p-type dopant, such as boron.

The device 300 can further include a seed layer 328 positioned over the n-type channel layers 308a-308b, and a top seed layer 330 over the seed layer 328. The seed layer 328 and the top seed layer 330 can be an epitaxial growth layer that includes one of Si, SiGe, Ge, or other suitable semiconductor materials. The top seed layer 330 can be configured to function as a substrate on which another subsequent 3D transistor stack can be formed. For example, a channel structure 300F can be formed over the top seed layer 330. In some embodiments, a high-k layer 332 can further be disposed around the seed layer 328. The high-k layer 332 can be one of HfO₂, ZrO₂, HfSiNO₂, ZrSiNO₂, Y₃O₄, Si₃N₄, and Al₂O₃.

The device 300 can include insulating layers 374 positioned between the n-type channel layers 308a-308b and the p-type channel layers 306a-306b. The insulating layers 374 can be arranged on the surfaces of the n-type channel layers 308a-308b and the p-type channel layers 306a-306b. Accordingly, the n-type gate structures 317 and the p-type gate structures 311 can be positioned between the insulating layers 374, and spaced apart from the n-type S/D structures 322 and the p-type S/D structures 314 by the insulating layers 374.

The device 300 can include a first isolation layer 326 positioned between a lowermost p-type gate structure of the p-type gate structures 311 and the substrate 302, where the lowermost p-type gate structure is disposed on a bottom surface of the lowermost p-type channel layer 306a. The device 300 can also include a second isolation layer 324 that is positioned between an uppermost n-type gate structure of the n-type gate structures 317 and the seed layer 328, where the uppermost n-type gate structure is disposed on a top surface of the uppermost n-type channel layer 308b.

The device 300 can include a first dielectric layer 341 and a second dielectric layer 342 positioned between the p-type S/D structures 314 and the substrate 302. The device 300 can include a dielectric layer 316 positioned over the p-type S/D structures 314. In some embodiments, the dielectric layer 316 can be a high-k layer.

The device 300 can include top dielectric layers 338 between which the second isolation layer 324 is positioned, and bottom dielectric layers 340 between which the first isolation layer 326 is positioned. In some embodiments, the first dielectric layer 341, the second dielectric layer 342, the top dielectric layers 338, and the bottom dielectric layers 340 can include SiO, SiN, SiON, SiC, or the like.

Still referring to FIG. 44, the device 300 can include structures 334 positioned over the dielectric layer 316 such that the n-type S/D structures 322 are positioned between the structures 334. In some embodiments, the structures 334 can be dielectric structures. In some embodiments, the structures 334 can be conductive structures and function as interconnects.

The device 300 can also include a cap layer 336 over the seed layer 328. The top seed layer 330 can be arranged in the cap layers 336.

In the device 300, the p-type channel layers 306a-306b, the p-type gate structures 311, and the p-type S/D structures 314 can form a p-type transistor 300A over the substrate 302. The n-type channel layers 308a-308b, the n-type gate structures 317, and the n-type S/D structures 322 can form a n-type transistor 300B over the p-type transistor 300A. Accordingly, a CFET structure can be formed based on the p-type transistor 300A and the n-type transistor 300B that are stacked over the substrate 302. The CFET structure can be positioned over the substrate 302, and arranged in a dielectric layer 304.

The device 300 can include a transistor stack 300E over the dielectric layer 304. The transistor stack 300E can include a stack of insulating layers 344a-344j and interconnect layers 346a-346f that are positioned alternatingly over the dielectric layer 304, and a hard mask layer 348 over the stack of insulating layers 344a-344j and interconnect layers 346a-346f. The transistor stack 300E can include the channel structure 300F positioned over the top seed layer 330 and extending through hard mask layer 348, the insulating layers 344a-344j and the interconnect layers 346a-346f. The channel structure 300F can include a first channel section 300C positioned over the top seed layer 330 and coupled to a first group of the interconnect layers 346a-346c, and a second channel section 300D positioned over the first channel section 300C and coupled to a second group of the interconnect layers 346d-346f.

In some embodiments, the first channel section 300C can include a first S/D region 358 that is positioned over the top seed layer 330 and in contact with a first interconnect layer 346a of the first group of the interconnect layers 346a-346f. The first channel section 300C can also include a first gate region over the first S/D region 358 of the first channel section 300C. The first gate region can include (i) a first channel region 360 over the first S/D region 358 and (ii) a first gate oxide 362 around the first channel region 360 and in contact with a second interconnect layer 346b of the first group of the interconnect layers 346a-346f. The first channel section 300C can include a second S/D region 364 over the first gate region and in contact with a third interconnect layer 346c of the first group of the interconnect layers 346a-346f.

The second channel section 300D can include a third S/D region 366 over the second S/D region 364 and in contact with a first interconnect layer 346d of the second group of the interconnect layers 346d-346f. The second channel section 300D can include a second gate region over the third S/D region 366. The second gate region can include (i) a second channel region 368 over the third S/D region 366 and (ii) a second gate oxide 370 around the second channel region 368 and in contact with a second interconnect layer 346e of the second group of interconnect layers 346d-346f. The second channel section 300D can further include a fourth S/D region 372 over the second gate region and in contact with a third interconnect layer 346f of the second group of interconnect layers 346d-346f.

The channel structure 300F can further include a first dielectric layer 350 positioned between the top seed layer 330 and the first S/D region 358 of the first channel section 300C, a second dielectric layer 352 positioned between the second S/D region 364 of the first channel section 300C and the third S/D region 366 of the second channel section 300D, a third dielectric layer 354 positioned over the fourth S/D region 372 of the second channel section 300D, and an isolation structure 356 extending from the first dielectric layer 350 and further through the first channel section 300C, the second dielectric layer 352, the second channel section 300D, and the third dielectric layer 354.

In some embodiments, the first S/D region 358 and the second S/D region 364 can be formed by a semiconductor material, such as Si, SiGe, Ge, or the like, and doped by a n-type dopant. The first channel region 360 can be intrinsic silicon. Accordingly, the first channel section 300C and the first group of the interconnect layers 346a-346c can form a n-type transistor. The third S/D region 366 and the fourth S/D region 372 can be formed by a semiconductor material doped by a p-type dopant. The second channel region 368 can be intrinsic silicon. Accordingly, the second channel section 300D and the second group of the interconnect layers 346d-346f can form a p-type transistor.

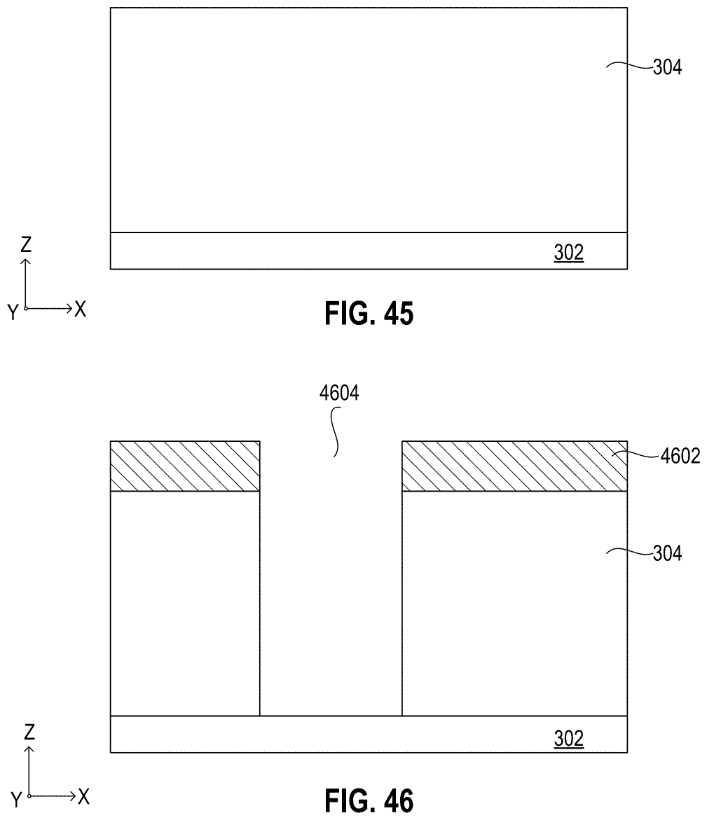

FIGS. 45-86 are top-down views and cross-sectional views of various intermediate steps in a manufacturing flow to fabricate the device 300, in accordance with some embodiments. As shown in FIG. 45, a dielectric layer 304 can be formed over a substrate 302. In some embodiments, the dielectric layer 304 can be a single layer. In some embodiments, the dielectric layer 304 can be a stack and include two or more layers. The dielectric layer 304 can include SiO, SiN, SiON, SiC, the like, or a combination thereof. The dielectric layer 304 can be formed by any suitable deposition techniques, such as a chemical vapor deposition (CVD) process, an atomic layer deposition (ALD) process, a diffusion process, or the like.

In FIG. 46, a mask layer 4602 with patterns can be formed over the dielectric layer 304 based on a photolithography process. An etching process can subsequently be applied to transfer the patterns of the mask layer into the dielectric layer 304 to form openings. For example, an opening 4604 can be illustrated in FIG. 46.

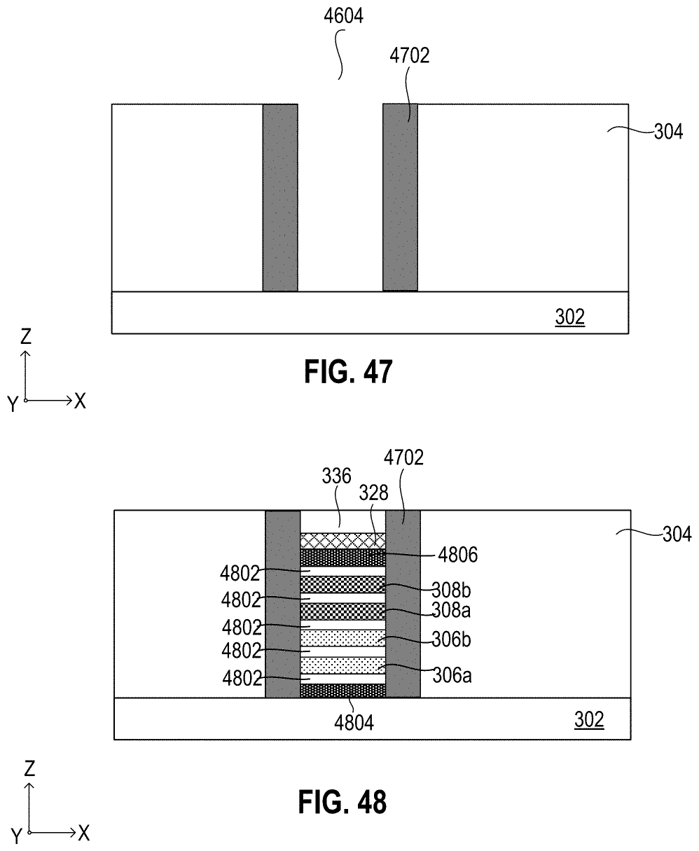

In FIG. 47, a spacer 4702 can be formed along sidewalls of the opening 4604. The spacer 4702 can be made of a dielectric material, such as SiO, SiN, SiON, SiC, or like. In some embodiments, the dielectric material can further be deposited on the substrate 302 through the opening 4604. Thus, a directional etching process can subsequently be applied to remove the dielectric material on the substrate 302, and the dielectric material formed along the sidewalls of the opening 4604 can still remain to form the spacer 4702.

In FIG. 48, a first transition layer 4804 can be formed in the opening 4604. The first transition layer 4804 can be arranged over the substrate 302 and in contact with the spacer 4702. A stack of channel layers 306a-306b and 308a-308b and intermediate layers 4802 can be alternatingly formed over first transition layer 4804. Further, a second transition layer 4806 can be formed over the stack of channel layers 306a-306b and 308a-308b and intermediate layers 4802, a seed layer 328 can be formed over the second transition layer 4806, and a cap layer 336 can be formed over the seed layer 328. In some embodiments, the cap layer 336 can include SiO, SiN, SiON, SiC, or like. The channel layers 306a-306b and 308a-308b, the intermediate layers 4802, the first transition layer 4804, and the second transition layer 4806 can include Si, SiG, Ge, or other suitable semiconductor materials. The channel layers 306a-306b and the 308a-308b can be doped with a dopant. In an exemplary embodiment of FIG. 48, the channel layers 306a-306b can be doped with a p-type dopant and the channel layers 308a-308b can be doped with a n-type dopant. Of course, the channel layers 306a-306b can also be doped with a n-type dopant and the channel layers 308a-308b can also be doped with a p-type dopant. Further, the intermediate layers 4802 can be made of SiGe, and the first and second transition layers 4804 and 4806 can be made of SiGe that has a different Ge content from the intermediate layers 4802.

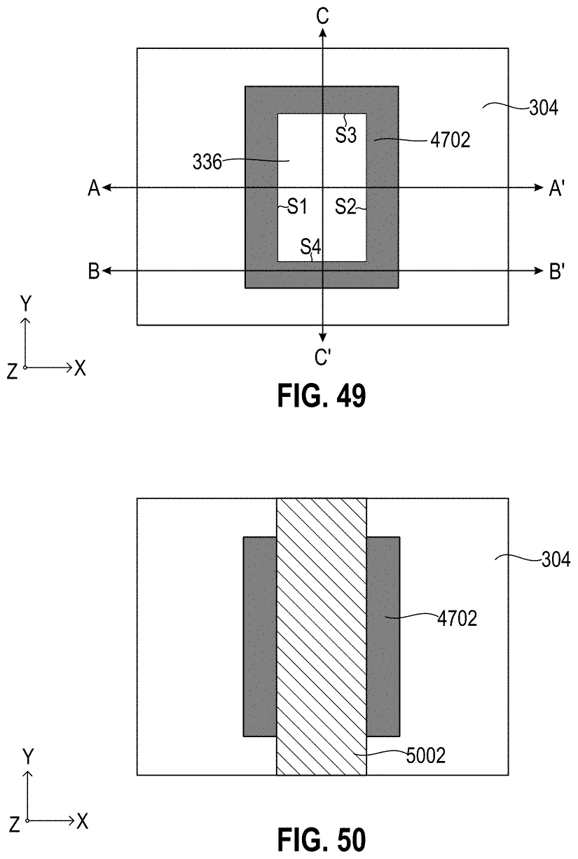

FIG. 49 is a top-down view of the structure shown in FIG. 48 when the cap layer 336 is formed. As shown, the cap layer 336 can be surrounded by the spacer 4702. In some embodiments, the cap layer 336 and the stack of channel layers 306a-306b and the 308a-308b can have a quadrilateral shape that includes the first, second, third, and fourth sides S1-S4. In addition, three cross-sectional directions A-A′, B-B′, and C-C′ are provided, which can be applied in subsequent cross-sectional views.

In FIG. 50, a mask layer 5002 can be formed to cover the cap layer 336. The mask layer 5002 can further extend along a horizontal direction (e.g., Y direction) parallel to the substrate 302 to cover portions of the spacer 4702 that are adjacent to the third side S3 and the fourth side S4 of the stack of channel layers 306a-306b and the 308a-308b. The mask layer 5002 can be a photoresist layer formed based on a photolithographic process.

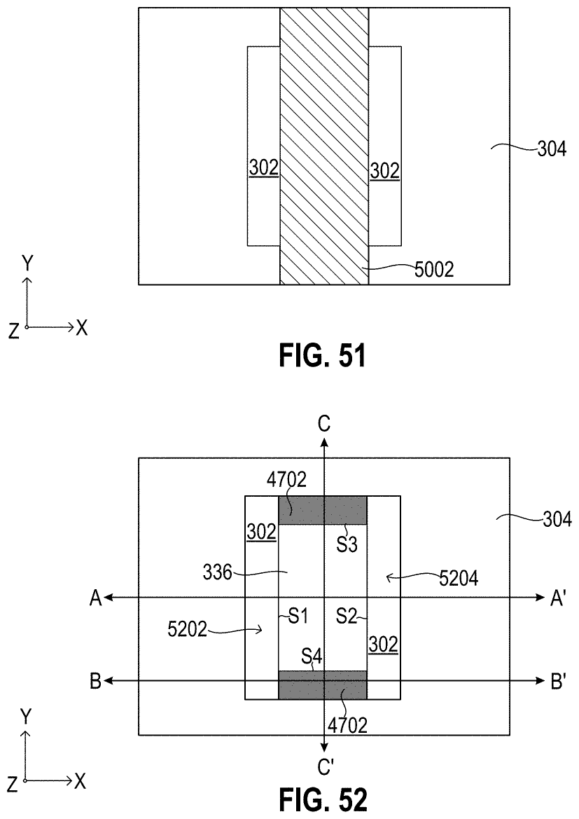

In FIG. 51, an etching process can be applied to remove portions of the spacer 4702 that are adjacent to the first side 51 and the second side S2 of the stack of channel layers 306a-306b and the 308a-308b. Accordingly, the substrate 302 can be uncovered by the etching process.

In FIG. 52, the mask layer 5002 can be removed by a plasma ashing process. As shown in FIG. 52, spaces 5202 and 5204 can be formed when the portions of the spacer 4702 that are adjacent to the first side 51 and the second side S2 of the stack of channel layers 306a-306b and the 308a-308b are removed. The substrate 302 can be uncovered in the spaces 5202 and 5204.

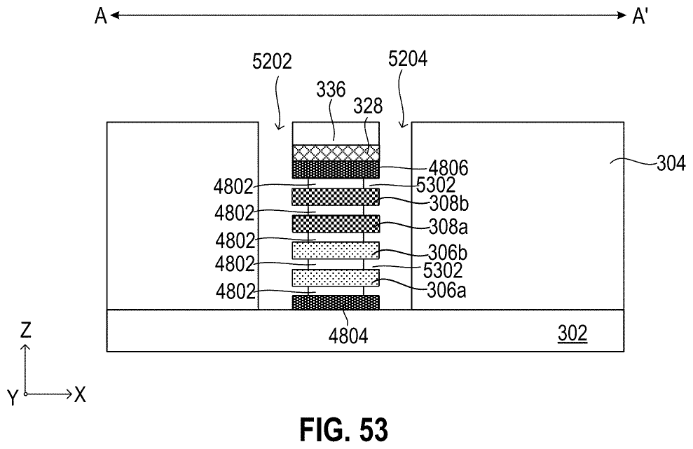

In FIG. 53, the intermediate layers 4802 can be recessed through a selective etching process, where the selective etching can remove portions of the intermediate layers 4802 from the first side S1 and the second side S2 of the stack of channel layers 306a-306b and the 308a-308b, and the channel layers 306a-306b and the 308a-308b are not impacted. Accordingly, spaces 5302 can be formed between the first transition layer 4804 and the substrate 302, between the channel layers 306a-306b and the 308a-308b, and between the second transition layer 4806 and an uppermost channel layer 308b. It should be noted that FIG. 53 is a cross-sectional view that is obtained from a same plane as a vertical plane along line A-A′ in FIG. 52.

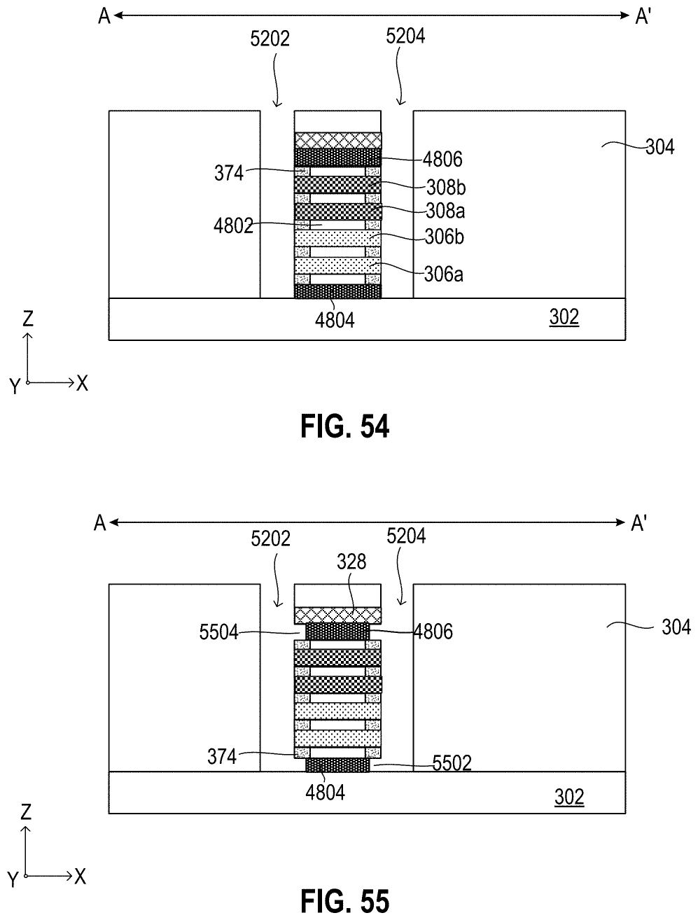

In FIG. 54, insulating layers 374 can be formed between the first transition layer 4804, the channel layers 306a-306b and the 308a-308b, and the second transition layer 4806. Accordingly, the intermediate layers 4802 can be disposed between the insulating layers 374. The insulating layer 374 can be made of any suitable dielectric material, such as SiN, SiO, SiCN, SiC, or the like. The insulating layers 374 can be formed by any suitable deposition process, such as a CVD process, an ALD process, and a diffusion process.

In FIG. 55, the first transition layers 4804 and the second transition layer 4806 can be recessed through a selective etching process. The selective etching process can introduce an etching plasma through the spaces 5202 and 5204 to remove portions of the first transition layers 4804 and the second transition layer 4806 from the first side Si and the second side S2 of the stack of channel layers 306a-306b and the 308a-308b. Accordingly, a space 5502 can be formed between a lowermost insulating layer of the insulating layers 374 and the substrate 302, and a space 5504 can be formed between an uppermost insulating layer of the insulating layers 374 and the seed layer 328.

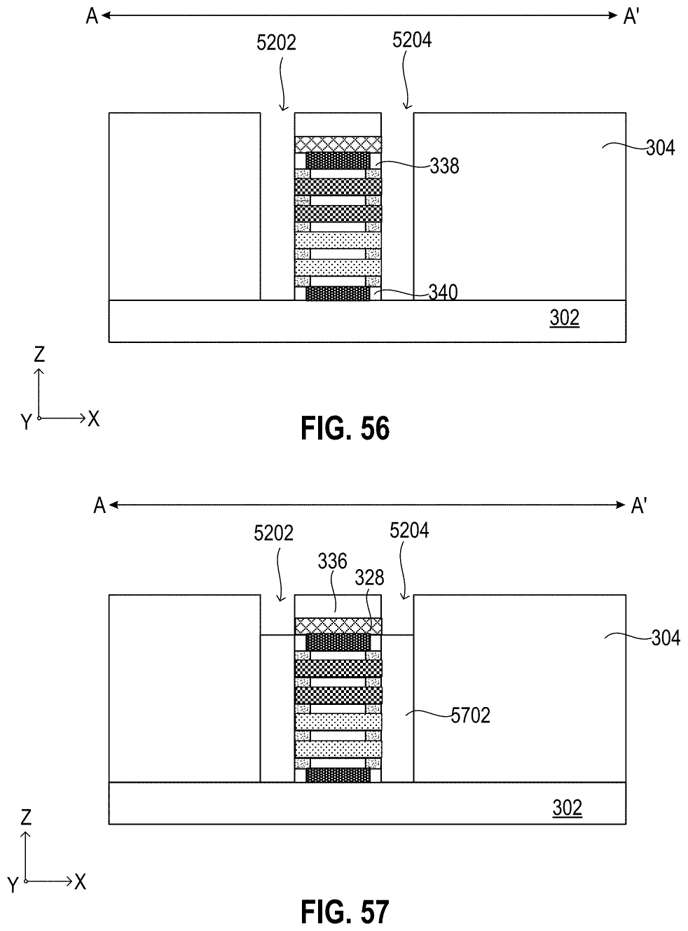

In FIG. 56, top dielectric layers 338 can be formed in the space 5504 and bottom dielectric layers 340 can be formed in the space 5502. In order to form the top dielectric layers 338 and the bottom dielectric layers 340, a selective deposition process can be applied to deposit a dielectric material in the spaces 5502 and 5504. The top dielectric layers 338 and the bottom dielectric layers 340 can include SiO, SiN, SiON, SiC, or the like.

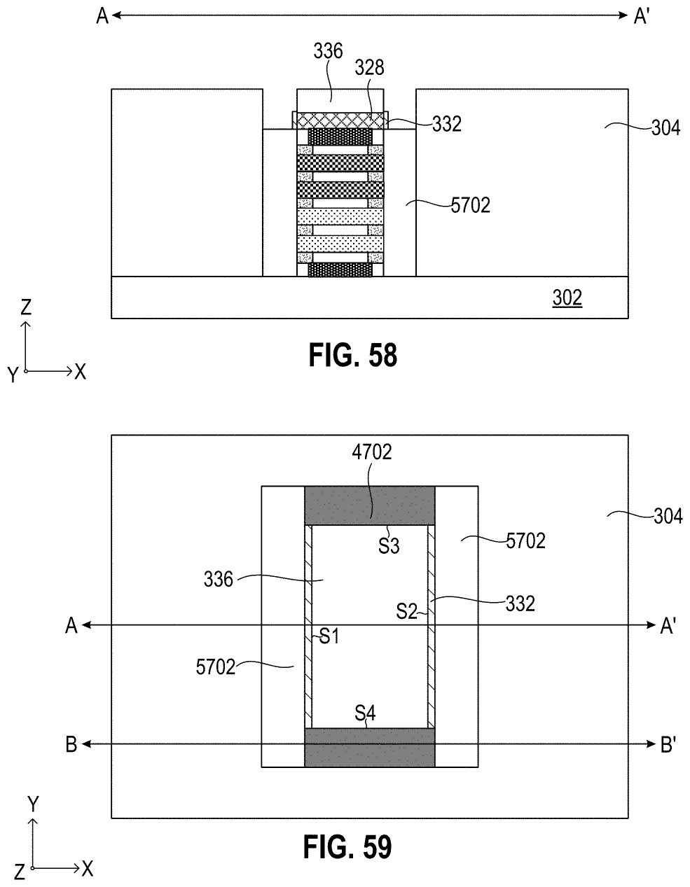

In FIG. 57, dielectric layers 5702 can be deposited to fill in the spaces 5202 and 5204. The dielectric layers 5702 can then be recessed to uncover the seed layer 328. In FIG. 58, a high-k layer 332 can further be disposed along sidewalls of the seed layer 328. The high-k layer 332 can be one of HfO₂, ZrO₂, HfSiNO₂, ZrSiNO₂, Y₃O₄, Si₃N₄, and Al₂O₃.

FIG. 59 shows a top down view when the high-k layer 332 is formed. As shown, the dielectric layer 5702 can be formed in the spaces 5202 and 5204 such that the stack of channel layers 306a-306b and the 308a-308b are arranged between the dielectric layers 5702. The high-k layer 332 can be formed along sidewalls of the seed layer 328 and positioned at the first side Si and the second side S2 of the stack of channel layers 306a-306b and the 308a-308b.

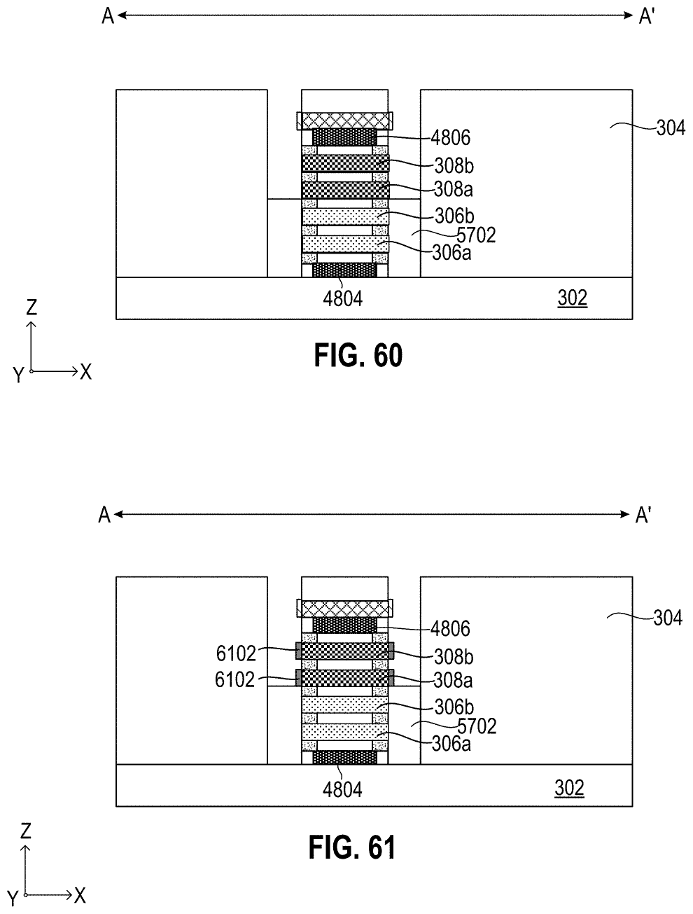

In FIG. 60, the dielectric layers 5702 can be recessed along a direction (e.g., Z direction) perpendicular to the substrate 302 to uncover the n-type channel layers 308a-308b. In FIG. 61, oxide layers 6102 can be formed at two ends of the channel layer 308a-308b, and positioned at the first side Si and the second side S2 of the stack of channel layers 306a-306b and the 308a-308b. The oxide layers 6102 can function as protective layers to the n-type channel layers 308a-308b in subsequent processes.

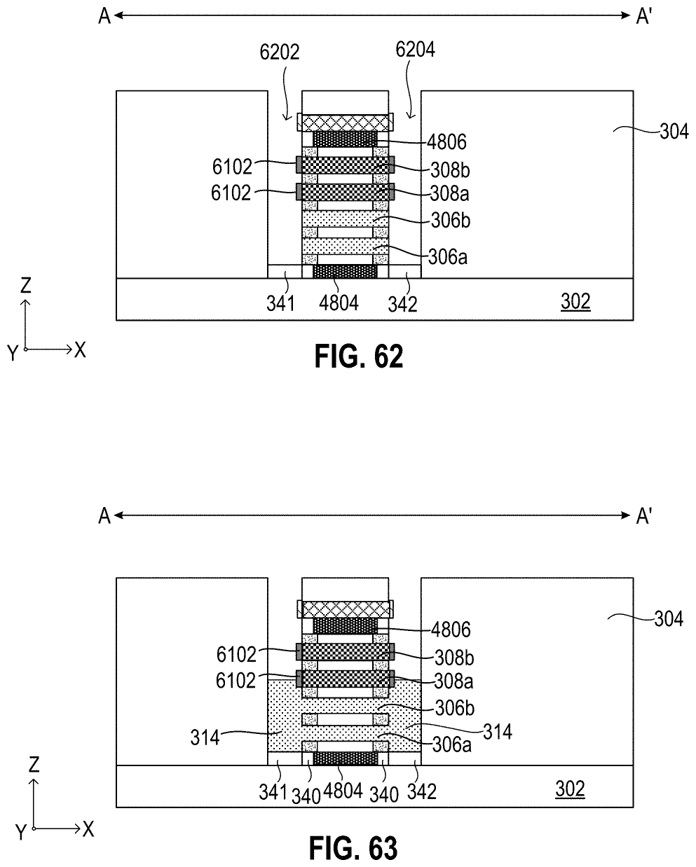

In FIG. 62, the dielectric layers 5702 can be recessed further. In some embodiments, the dielectric layers 5702 can be recessed to have a height approximately equal to a height of the first transition layer 4804. The remaining dielectric layers 5702 can become the a first dielectric layer 341 positioned over the substrate 302 and along the first side S1 of the stack of channel layers 306a-306b and 308a-308b, and a second dielectric layer 342 positioned over the substrate 102 and adjacent to the second side S2 of the stack of channel layers 306a-306b and 308a-308b. Further, a space 6202 can be formed at the first side S1 of the stack of channel layers 306a-306b and 308a-308b, and a space 6204 can be formed at the second side S2 of the stack of channel layers 306a-306b and 308a-308b.

In FIG. 63, p-type S/D structures 314 can be formed in the spaces 6202 and 6204, and arranged over the first dielectric layer 341 and the second dielectric layer 342. The p-type S/D structures 314 can be in contact with the p-type channel layers 306a-306b and positioned at the first side Si and the second side S2 of the stack of channel layers 306a-306b and the 308a-308b. Accordingly, the p-type channel layers 306a-306b can be arranged between the p-type S/D structures 314.

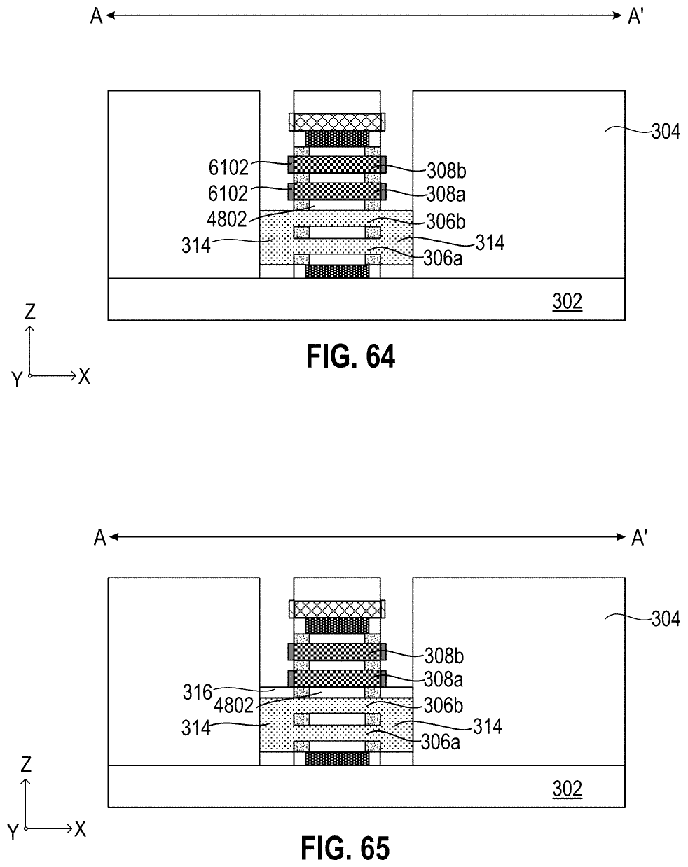

In some embodiments, as shown in FIG. 64, the p-type S/D structures 314 can further be recessed along the direction (e.g., Z direction) perpendicular to the substrate 302 to uncover the intermediate layer 4802 that is positioned under the n-type channel layer 308a.

In FIG. 65, a dielectric layer 316 can be formed over the p-type S/D structures 314. As shown in FIG. 65, the dielectric layer 316 can be positioned under the n-type channel layer 308a. In some embodiments, the dielectric layer 316 can be level with the intermediate layer 4802 that is positioned under the n-type channel layer 308a in the Z direction. In some embodiments, the dielectric layer 316 can be a high-k layer.

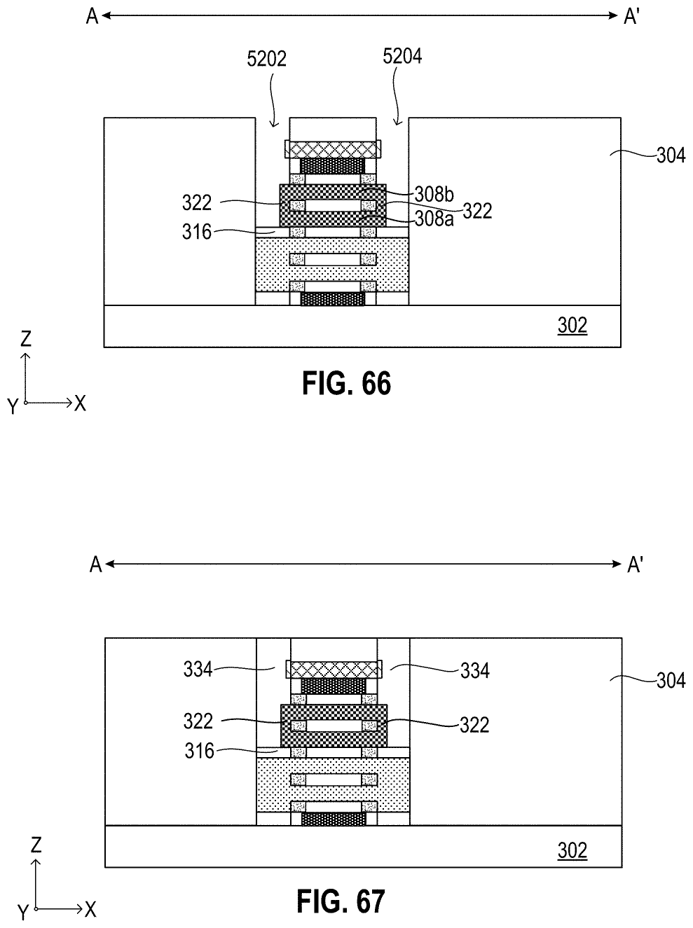

In FIG. 66, the oxide layers 6102 can be removed and n-type S/D structures 322 can be formed over the dielectric layer 316. The n-type S/D structures 322 can be in contact with the n-type channel layers 308a-308b and positioned at the first side Si and the second side S2 of the stack of channel layers 306a-306b and the 308a-308b. Accordingly, the n-type channel layers 308a-308b can be arranged between the n-type S/D structures 322.

In FIG. 67, structures 334 can be formed over the dielectric layer 316 such that the n-type S/D structures 322 are positioned between the structures 334. In some embodiments, the structures 334 can be dielectric structures. In some embodiments, the structures 334 can be conductive structures and function as interconnects.

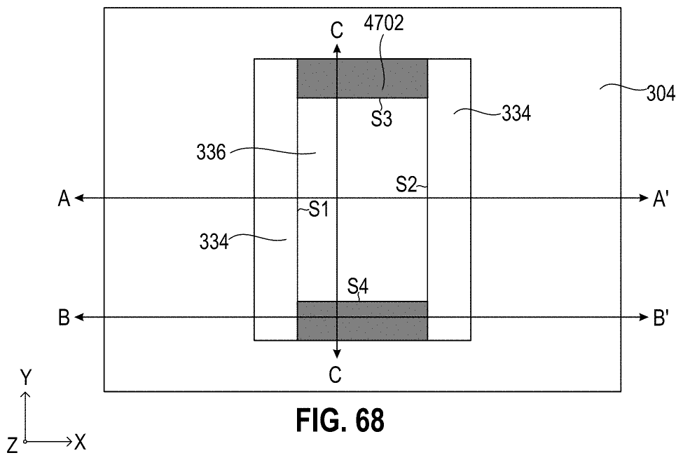

FIG. 68 shows a top down view of the structures 334. As shown in FIG. 68, the structures 334 can be positioned at the first side Si and the second side S2 of the stack of channel layers 306a-306b and the 308a-308b. In addition, the spacer 4702 is arranged at the third side S3 and the fourth side S4 of the stack of channel layers 306a-306b and the 308a-308b.

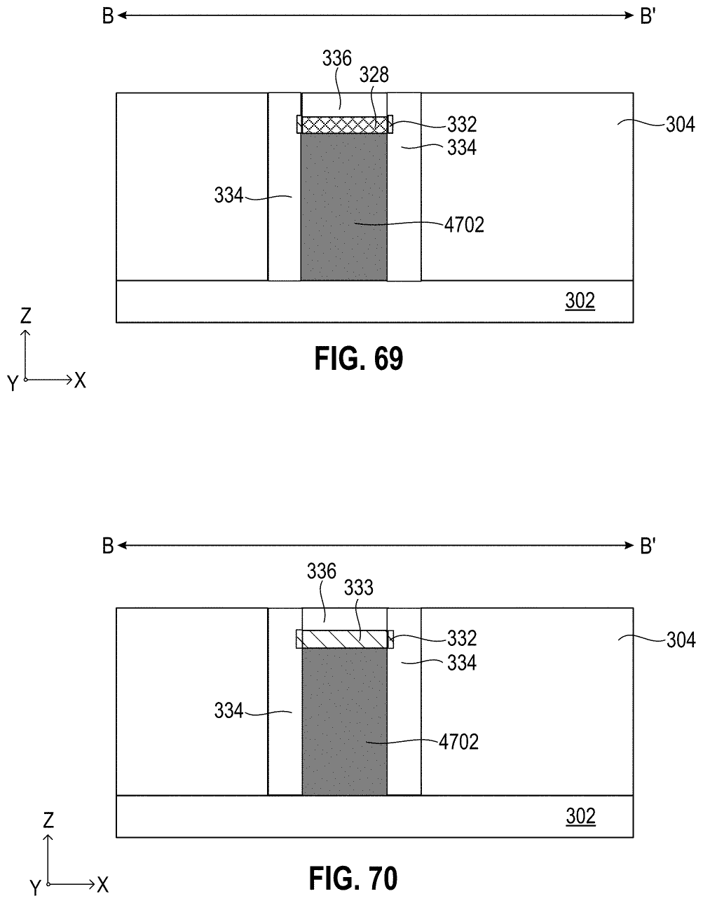

In FIG. 69, the spacer 4702 and the structures 334 can be recessed by a selective etching process along a direction (e.g., Z direction) perpendicular to the substrate 302. Accordingly, the cap layer 336, the seed layer 328, and the high-k layer 332 can be uncovered by the selective etching process. The structures 334 may not affected by the selective etching process. The cross-sectional view of FIG. 69 is obtained from a same plane as a vertical plane along line B-B′ in FIG. 68.

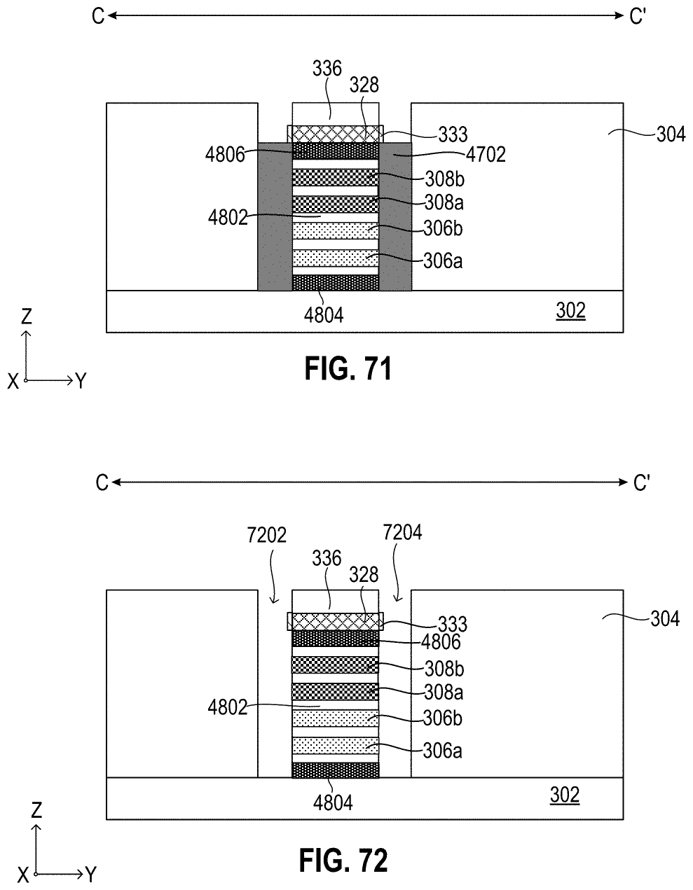

In FIG. 70, a high-k layer 333 can be formed along sidewalls of the seed layer 328 and positioned at the third side S3 and the fourth side S4 of the stack of channel layers 306a-306b and the 308a-308b. Accordingly, the seed layer 328 can be surrounded by the high-k layers 332 and 333. FIG. 71 is a cross-sectional view of FIG. 70 is obtained from a same plane as a vertical plane along line C-C′ in FIG. 68.

In FIG. 72, the spacer 4702 can be removed by a selective etching process, where the channel layers 306a-306b and 308a-308b, the intermediate layers 4802, the first and second transition layers 4804 and 4806 are not affected. Accordingly, spaces 7202 and 7204 can be formed. The channel layers 306a-306b and 308a-308b, and the intermediate layers 4802 can be uncovered by the spaces 7202 and 7204.

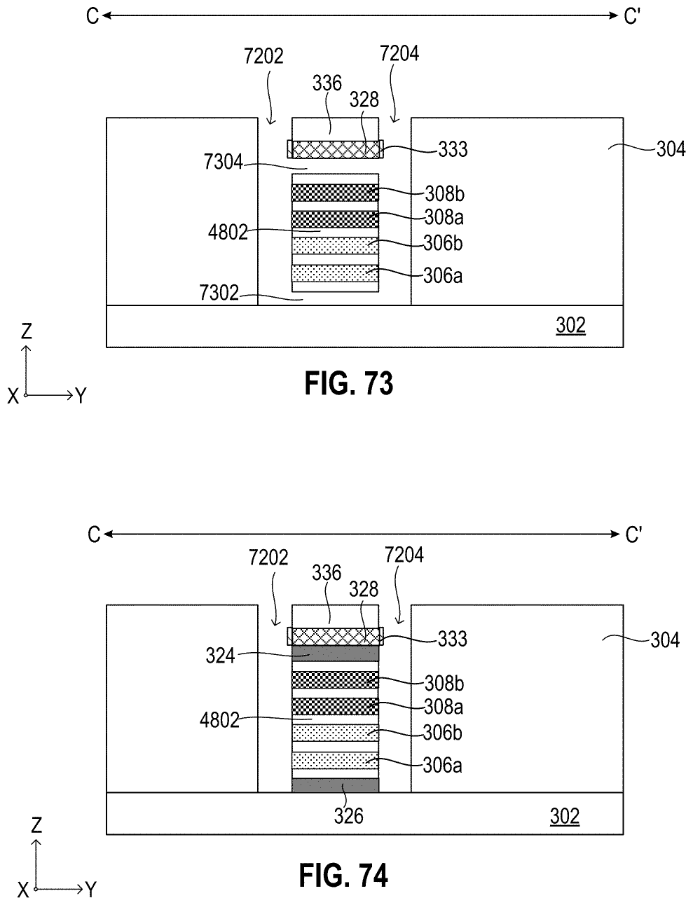

In FIG. 73, the first and second transition layers 4804 and 4806 can be removed by a selective etching process, where the selective etching process can introduce an etching plasma or an etching chemical through the spaces 7202 and 7204 to remove the first and second transition layers 4804 and 4806. In the meanwhile, the channel layers 306a-306b and 308a-308b, and the intermediate layers 4802 are not affected by the selective etching process. When the selective etching process is completed, a space 7302 can be formed between the substrate 302 and the lower most intermediate layer 4802, and a space 7304 can be formed between the seed layer 328 and the uppermost intermediate layer 4802.

In FIG. 74, a dielectric material can be deposited in the spaces 7302 and 7304 to form a first isolation layer 326 and a second isolation layer 324 respectively. As shown in FIG. 74, the first isolation layer 326 can be formed between the lowermost intermediate layer 4802 and the substrate 302, and the second isolation layer 324 can be formed between the uppermost intermediate layer 4802 and the seed layer 328.

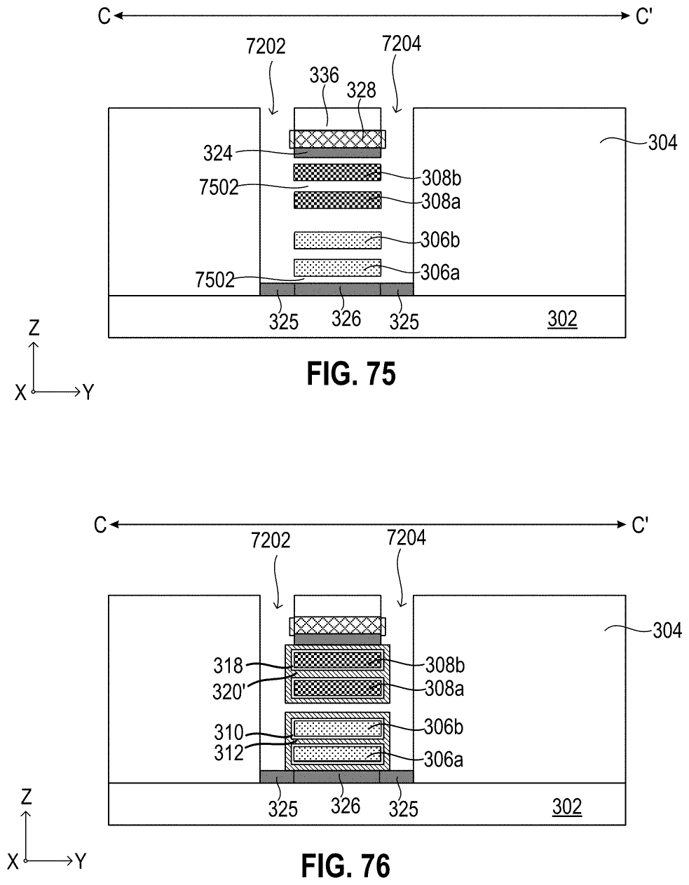

In FIG. 75, the intermediate layers 4802 can be removed by a selective etching process, and the channel layers 306a-306b and 308a-308b can still remain. Accordingly, spaces 7502 can be formed between the second isolation layer 324 and the channel layer 308b, between the channel layers 306a-306b and 308a-308b, and between the channel layer 306a and the substrate 302. In some embodiments, insulating layers 325 can be deposited through the spaces 7202 and 7204. The insulating layers 325 can be deposited over the substrate 302, and the first isolation layer 326 can accordingly be positioned between the insulating layers 325.

In FIG. 76, gate dielectric layers 318 can be formed on the surfaces of the n-type channel layers 308a-308b, and gate dielectric layers 310 can be formed on the surfaces of the p-type channel layers 306a-306b. Further, a gate material can be deposited in the spaces 7502 to form gate electrode layers 320′ and 312. The gate electrode layers 320′ can be formed along and in contact with the gate dielectric layers 318. The gate electrode layers 312 can be formed along and in contact with the gate dielectric layers 310. In an example of FIG. 76, the gate electrode layers 320′ and 312 can be made of same materials. For example, the gate material can include a work function layer (e.g., TiON or TiC), a liner (e.g., TiN or TaN), and a filler (e.g., W or Ru).

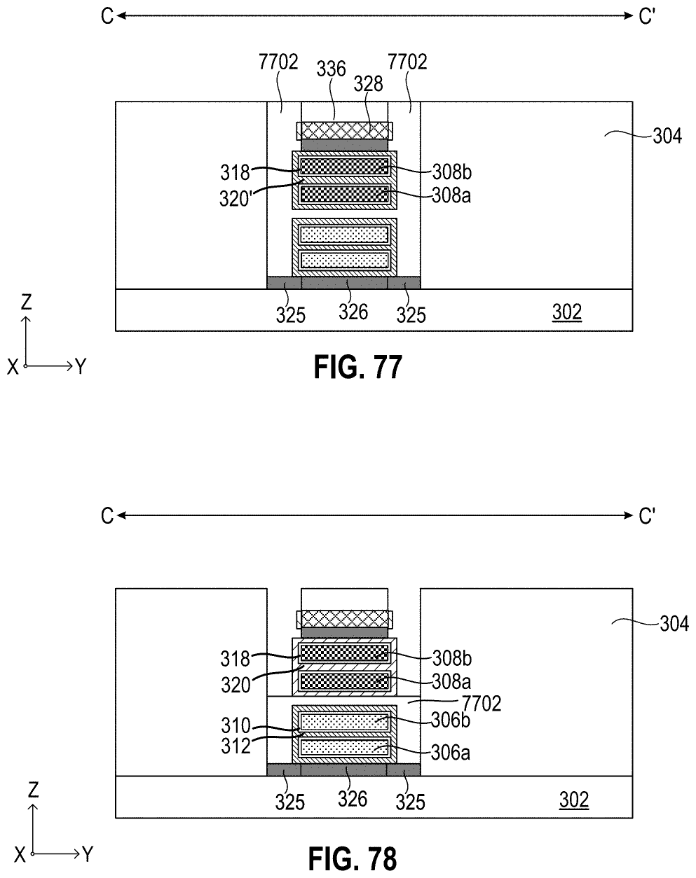

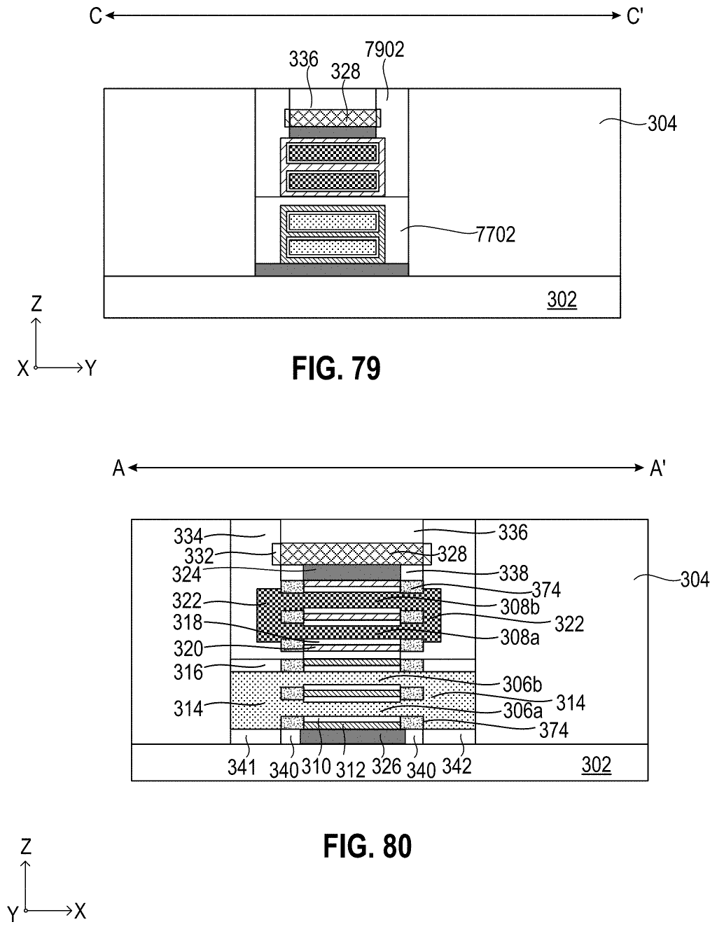

FIGS. 77-80 show manufacturing steps to form the gate electrode layers 320 that are made of materials different from the gate electrode layers 312. As shown in FIG. 77, dielectric layers 7702 can be deposited to fill in the spaces 7202 and 7204. In FIG. 78, the dielectric layers 7702 can be recessed along the Z direction such that the gate electrode layers 320′ can be uncovered and removed subsequently. Further, gate electrode layers 320 can be formed. In some embodiments, the gate electrode layers 320 can include a work function layer (e.g., TiC), a liner (e.g., TiN), and a filler (e.g., W or Ru). The gate electrode layer 312 can include a work function layer (e.g., TiON, TiC), a liner (e.g., TiN and/or TaN), and a filler (e.g., W or Ru). In FIG. 79, dielectric layers 7902 can be formed over the dielectric layers 7702. FIG. 80 shows a cross-sectional view along the direction A-A′ when the gate electrode layers 320 are formed.

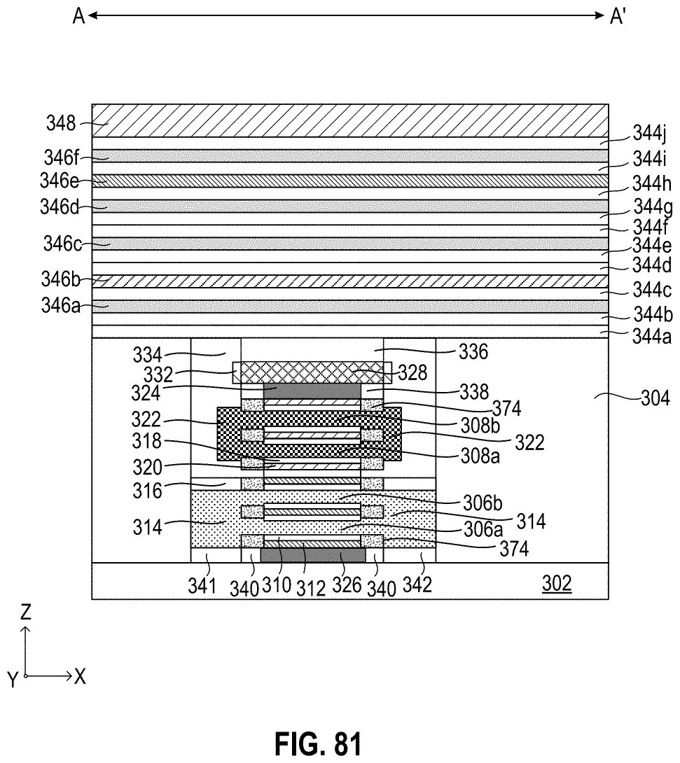

In FIG. 81, a stack of alternating insulating layers 344a-344j and interconnect layers 346a-346f can be formed over the dielectric layer 304, and a hard mask layer 348 can be formed on the insulating layer 344j. The insulating layers 344a-344j can be made of a dielectric material, such as SiO or SiN. The interconnect layers 346a-346f can be made of a conductive material, such as W or polysilicon.

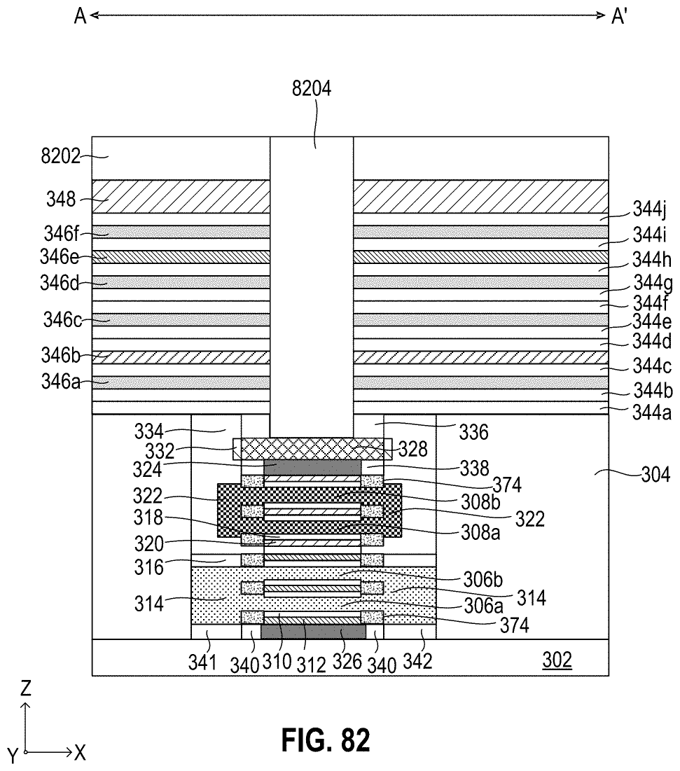

In FIG. 82, a mask layer 8202 with patterns can be formed over the hard mask layer 348 through a photolithography process. An etching process can subsequently be applied to transfer the patterns into hard mask layer 348, the insulating layer 344a-344j, and the interconnect layers 346a-346f to form an opening 8204. The opening 8204 can extend through the cap layer 336 to uncover the seed layer 328.

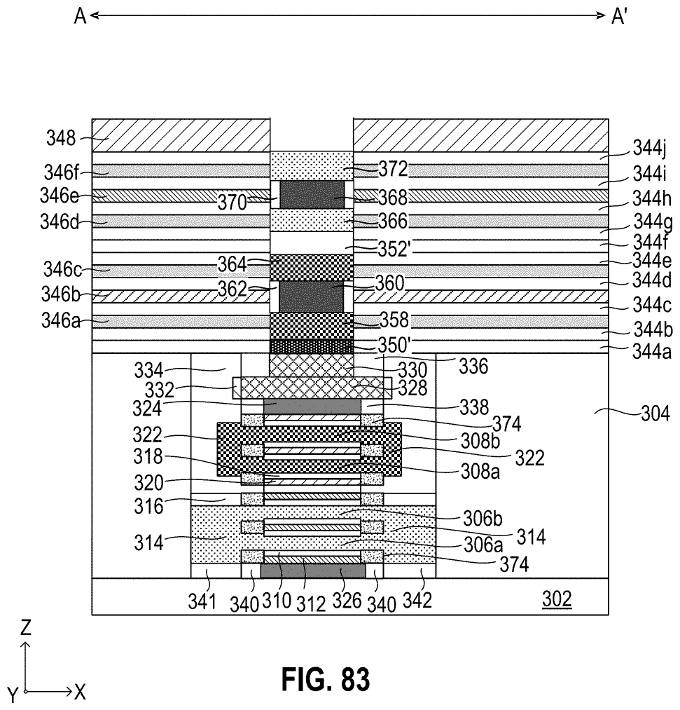

In FIG. 83, a top seed layer 330 can be formed over the seed layer 328. Further, a first dummy layer 350′ is formed on the top seed layer 330. A first S/D region 358 is formed on the first dummy layer 350′ and in contact with the interconnect layer 346a. A first gate oxide 362 and a first channel region 360 are formed on the first S/D region 358, where the first gate oxide 362 is around the first channel region 360 and in contact with the interconnect layer 346b. A second S/D region 364 is formed over the first gate oxide 362 and the first channel region 360, where the second S/D region 346 is in contact with the interconnect layer 346c. A second dummy layer 352′ is formed on the second S/D region 364. A third S/D region 366 is formed over the second dummy layer 352′ and in contact with the interconnect layer 346d. A second gate oxide 370 and a second channel region 368 are formed over the third S/D region 366, where the second gate oxide 370 is around the second channel region 368 and in contact with the interconnect layer 346e. A fourth S/D region 372 is formed over the second gate oxide 370 and the second channel region 368 and in contact with the interconnect layer 346f.

In some embodiments, the first dummy layer 350′ and the second dummy layer 352′ can be made of SiGe. The first S/D region 358 and the second S/D region 364 can be made of Si, SiGe, Ge, or the like, and doped with a n-type dopant. The third S/D region 366 and the fourth S/D region 372 can be made of Si, SiGe, Ge, or the like, and doped with a p-type dopant. The first channel region 360 and the second channel region 368 can be made of silicon.

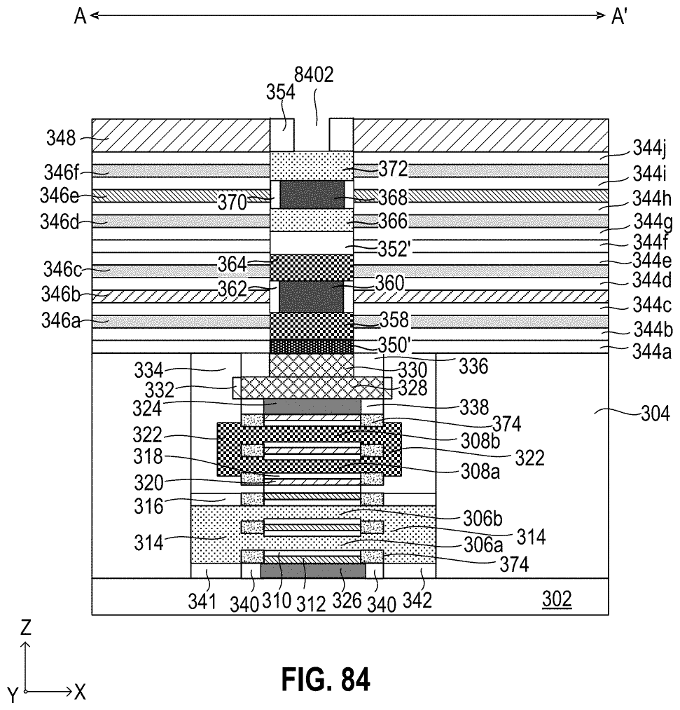

In FIG. 84, a dielectric layer 354 can be formed over the fourth S/D region 372. Further, a pattern 8402 can be formed in the dielectric layer 354 to uncover the fourth S/D region 372.

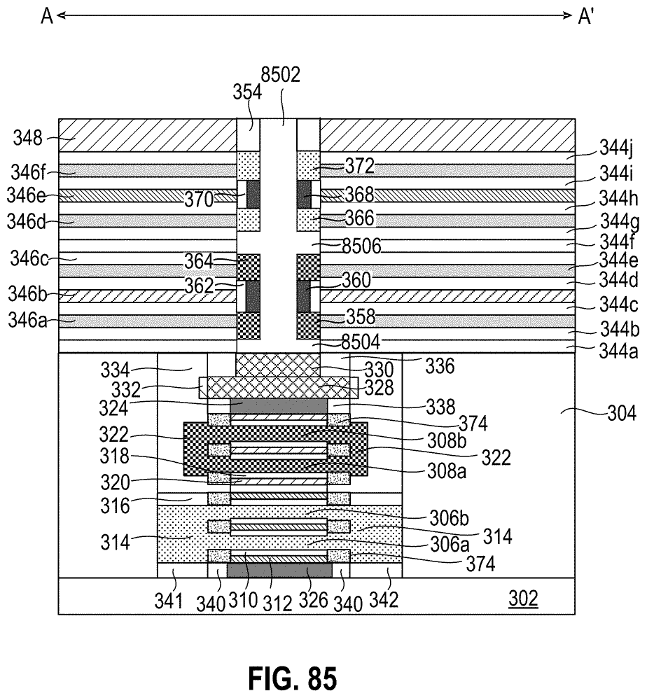

In FIG. 85, the dielectric layer 354 can function as a mask layer and a directional etching process can be applied based on the mask layer to etch through the first dummy layer 350′, the first S/D region 358, the first channel region 360, the second S/D region 364, the second dummy layer 352′, the third S/D region 366, the second channel region 368, and the fourth S/D region 372. Accordingly, an opening 8502 can be formed to uncover the top seed layer 330. The first dummy layer 350′ and the second dummy layer 352′ can be removed to form a space 8504 between the top seed layer 330 and the first S/D region 358, and a space 8506 between the second S/D region 364 and the third S/D region 366.

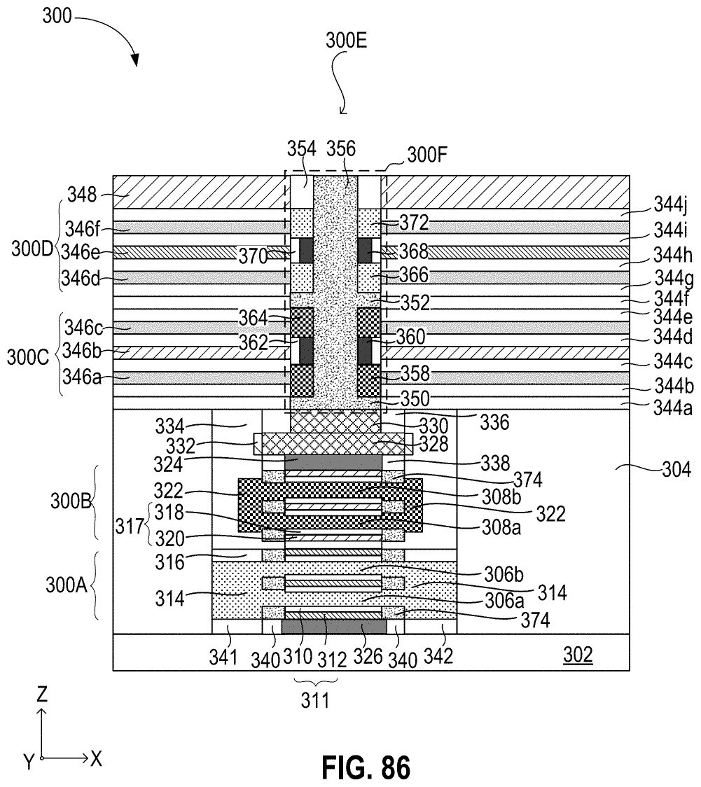

In FIG. 86, a dielectric material can be subsequently deposited into the spaces 8504 and 8506 and the opening 8502. Accordingly, a first dielectric layer 350 can be formed between the top seed layer 330 and the first S/D region 358, and a second dielectric layer 352 can be formed between the second S/D region 364 and the third S/D region 366. The dielectric layer 354 can be a third dielectric layer 354, and an isolation structure 356 can be formed extending through the first dielectric layer 350, the first S/D region 358, the first channel region 360, the second S/D region 364, the second dielectric layer 352, the third S/D region 366, the second channel region 368, and the fourth S/D region 372. When the first dielectric layer 350, the second dielectric layer 352, and the isolation structure 356 are formed, a device 300 can be formed accordingly, which can be identical to the device 300 shown in FIG. 44.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a stack of channel layers positioned over a substrate, the channel layers being spaced apart from one another;
source/drain (S/D) structures positioned at a first side and a second side of the stack of channel layers and in contact with the channel layers, the first side being opposite to the second side;
gate dielectric layers arranged around the channel layers, and gate electrodes surrounding the gate dielectric layers and further extending from a third side and a fourth side of the stack of channel layers, the third side being opposite to the fourth side; and
a seed layer positioned over the stack of channel layers.

2. The semiconductor device of claim 1, further comprising:
insulating layers positioned between the channel layers and arranged on surfaces of the channel layers, wherein
the gate dielectric layers and the gate electrodes are positioned between the insulating layers, and spaced apart from the S/D structures by the insulating layers.

3. The semiconductor device of claim 1, further comprising:
a high-k layer disposed around the seed layer.

4. The semiconductor device of claim 1, further comprising:
a first high-k layer positioned between a first gate electrode of the gate electrodes and the substrate;
a second high-k layer positioned between a second gate electrode of the gate electrodes and the substrate;
a first dielectric layer positioned between a first S/D structure of the S/D structures and the substrate; and
a second dielectric layer positioned between a second S/D structure of the S/D structures and the substrate.

5. The semiconductor device of claim 1, wherein:
the channel layers further include n-type channel layers and p-type channel layers that are stacked over the substrate;
the gate electrodes further include n-type gate electrodes and p-type gate electrodes that are stacked over the substrate, the n-types gate electrodes being arranged around the n-type channel layers, the p-types gate electrodes being arranged around the p-type channel layers; and
the S/D structures further include n-type S/D structures and p-type S/D structures that are stacked over the substrate, the n-type channel layers being positioned between and coupled to the n-type S/D structures, the p-type channel layers being positioned between and coupled to the p-type S/D structures.

6. The semiconductor device of claim 5, wherein:
the n-type S/D structures and the n-type channel layers are made of silicon that is epitaxially deposited and doped with a n-type dopant, and
the p-type S/D structures and the p-type channel layers are made of silicon that is epitaxially deposited and doped with a p-type dopant.

7. The semiconductor device of claim 1, further comprising:
a stack of insulating layers and interconnect layers that are positioned alternatingly over the stack of channel layers; and
a channel structure positioned over the seed layer and extending through the insulating layers and the interconnect layers, the channel structure including a first channel section positioned over the seed layer and coupled to a first group of the interconnect layers, and a second channel section positioned over the first channel section and coupled to a second group of the interconnect layers.

8. The semiconductor device of claim 7, wherein:
a first S/D region of the first channel section is formed over the seed layer and in contact with a first interconnect layer of the first group of the interconnect layers;
a first gate region of the first channel section is formed over the first S/D region of the first channel section, the first gate region including (i) a first channel region over the first S/D region and (ii) a first gate oxide around the first channel region and in contact with a second interconnect layer of the first group of the interconnect layers;
a second S/D region of the first channel section is formed over the first gate region and in contact with a third interconnect layer of the first group of the interconnect layers;
a third S/D region of the second channel section is formed over the second S/D region and in contact with a first interconnect layer of the second group of the interconnect layers;
a second gate region of the second channel section is formed over the third S/D region, the second gate region including (i) a second channel region over the third S/D region and (ii) a second gate oxide around the second channel region and in contact with a second interconnect layer of the second group of the interconnect layers; and
a fourth S/D region of the second channel section is formed over the second gate region and in contact with a third interconnect of the second group of the interconnect layers.

9. The semiconductor device of claim 8, further comprising:
a first dielectric layer positioned between the seed layer and the first S/D region of the first channel section;
a second dielectric layer positioned between the second S/D region of the first channel section and the third S/D region of the second channel section;
a third dielectric layer positioned over the fourth S/D region of the second channel section; and
an isolation structure extending from the first dielectric layer and further through the first channel section, the second dielectric layer, the second channel section, and the third dielectric layer.

10. A semiconductor device, comprising:
a horizontal transistor over a substrate, the horizontal transistor including (i) a stack of channel layers over the substrate and extending parallel to a main surface of the substrate, (ii) S/D structures positioned at a first side and an opposing second side of the stack of channel layers, and (iii) gate structures surrounding the channel layers and further extending from a second side and an opposing third side of the stack of channel layers;
a seed layer positioned over the stack of channel layers; and
a vertical transistor positioned over the horizontal transistor, the vertical transistor including a stack of insulating layers and interconnect layers over the stack of channel layers, a channel structure positioned over the seed layer and extending through the insulating layers and the interconnect layers in a direction orthogonal to the main surface of the substrate, the channel structure including a first channel section positioned over the seed layer and coupled to a first group of the interconnect layers, and a second channel section positioned over the first channel section and coupled to a second group of the interconnect layers.

11. The semiconductor device of claim 10, wherein the horizontal transistor further comprises:
n-type channel layers and p-type channel layers that are stacked over the substrate;
the gate structures further include n-type gate structures and p-type gate structures, the n-types gate structures being positioned around the n-type channel layers, the p-types gate structures being positioned around the p-type channel layers; and
the S/D structures further include n-type S/D structures and p-type S/D structures that are stacked over the substrate, the n-type channel layers being positioned between and coupled to the n-type S/D structures, the p-type channel layers being positioned between and coupled to the p-type S/D structures.

12. The semiconductor device of claim 10, wherein the vertical transistor further comprises:
a first S/D region of the first channel section that is formed over the seed layer and in contact with a first interconnect layer of the first group of the interconnect layers;
a first gate region of the first channel section that is formed over the first S/D region of the first channel section, the first gate region including (i) a first channel region over the first S/D region and (ii) a first gate oxide around the first channel region and in contact with a second interconnect layer of the first group of the interconnect layers;
a second S/D region of the first channel section that is formed over the first gate region and in contact with a third interconnect layer of the first group of the interconnect layers;
a third S/D region of the second channel section that is formed over the second S/D region and in contact with a first interconnect layer of the second group of the interconnect layers;
a second gate region of the second channel section that is formed over the third S/D region, the second gate region including (i) a second channel region over the third S/D region and (ii) a second gate oxide around the second channel region and in contact with a second interconnect layer of the second group of the interconnect layers; and
a fourth S/D region of the second channel section that is formed over the second gate region and in contact with a third interconnect of the second group of the interconnect layers.

13. A method of forming a semiconductor device, comprising:
forming a stack of alternating channel layers and intermediate layers over a substrate;
forming source/drain (S/D) structures at a first side and a second side of the stack and in contact with the channel layers, the first side being opposite to the second side;
replacing the intermediate layers with gate structures, the gate structures including (i) gate dielectric layers arranged around the channel layers, and (ii) gate electrodes surrounding the gate dielectric layers and further extending from a third side and a fourth side of the stack, the third side being opposite to the fourth side; and
forming a seed layer over the stack of alternating channel layers and intermediate layers.

14. The method of claim 13, before the S/D structures are formed, further comprising:
recessing the intermediate layers from the first side and the second side of the stack to form recessed spaces; and
forming insulating layers in the recessed spaces and between the channel layers such that the intermediate layers are positioned between the insulating layers.

15. The method of claim 13, further comprising:
forming a first high-k layer between a first gate electrode of the gate electrodes and the substrate;
forming a second high-k layer between a second gate electrode of the gate electrodes and the substrate;
forming a first dielectric layer between a first S/D structure of the S/D structures and the substrate; and
forming a second dielectric layer between a second S/D structure of the S/D structures and the substrate.

16. The method of claim 13, further comprising:
forming a high-k layer around the seed layer.

17. The method of claim 13, wherein:
the channel layers further include n-type channel layers and p-type channel layers that are stacked over the substrate;
the gate structures further include n-type gate structures and p-type gate structures, the n-types gate structures being positioned between the n-type channel layers and arranged on surfaces of the n-type channel layers, the p-types gate structures being positioned between the p-type channel layers and arranged on surfaces of the p-type channel layers; and
the S/D structures further include n-type S/D structures and p-type S/D structures that are stacked over the substrate, the n-type channel layers being positioned between and coupled to the n-type S/D structures, the p-type channel layers being positioned between and coupled to the p-type S/D structures.

18. The method of claim 13, further comprising:
forming a stack of insulating layers and interconnect layers that are positioned alternatingly over the stack of alternating channel layers and intermediate layers; and
forming a channel structure that is positioned over the seed layer and extend through the insulating layers and the interconnect layers, the channel structure including a first channel section positioned over the seed layer and coupled to a first group of the interconnect layers, and a second channel section positioned over the first channel section and coupled to a second group of the interconnect layers.

19. The method of claim 18, wherein the forming the channel structure further comprises:
forming a first opening extending through the insulating layers and the interconnect layers such that the seed layer is uncovered;
forming a first sacrificial layer on the seed layer;
forming a first S/D region of the first channel section over the first sacrificial layer, a first gate region of the first channel section over the first S/D region, and a second S/D region of the first channel section over the first gate region;
forming a second sacrificial layer over the second S/D region of the first channel section;
forming a third S/D region of the second channel section over the second sacrificial layer, a second gate region of the second channel section over the third S/D region, and a fourth S/D region of the second channel section over the second gate region;
forming a second opening extending through the fourth S/D region, the second gate region, the third S/D region, the second sacrificial layer, the second S/D region, the first gate region, the first S/D region, and the first sacrificial layer to uncover the seed layer;
removing the first and second sacrificial layers to form a first space between the seed layer and the first S/D region and a second space between the second S/D region and the third S/D region; and
filling the second opening, the first space, and the second space with a dielectric material.

20. The method of claim 19, wherein:
the first S/D region is in contact with a first interconnect layer of the first group of the interconnect layers;
the first gate region includes (i) a first channel region over the first S/D region and (ii) a first gate oxide around the first channel region and in contact with a second interconnect layer of the first group of the interconnect layers;
the second S/D region is in contact with a third interconnect layer of the first group of the interconnect layers;
the third S/D region is in contact with a first interconnect layer of the second group of the interconnect layers;
the second gate region includes (i) a second channel region over the third S/D region and (ii) a second gate oxide around the second channel region and in contact with a second interconnect layer of the second group of the interconnect layers; and
the fourth S/D region is in contact with a third interconnect of the second group of the interconnect layers.
